(19) United States
(12) Patent Application Publication
(10) Pub. No.: US 2025/0391452 A1
(43) Pub. Date: Dec. 25, 2025

(54) REGISTER CLOCK DRIVER AND MEMORY MODULE INCLUDING THE SAME

(71) Applicant: SAMSUNG ELECTRONICS CO., LTD., Suwon-si (KR)

(72) Inventor: Youngtaek CHO, Suwon-si (KR)

(73) Assignee: SAMSUNG ELECTRONICS CO., LTD., Suwon-si (KR)

(21) Appl. No.: 19/028,758

(22) Filed: Jan. 17, 2025

(30) Foreign Application Priority Data
Jun. 21, 2024 (KR) 10-2024-0081372

(51) Int. Cl. G11C 8/18

(52) U.S. Cl. CPC G11C 8/18

(57) ABSTRACT

Provided is a register clock driver including an input node configured to receive an input signal from a memory controller, an output node configured to output an output signal to a memory device, and an operating circuit configured to buffer the input signal and including a source circuit, a combination logic circuit, and a sink circuit, the source circuit including source flip-flop, and the sink circuit including sink flip-flops. The source circuit is configured to receive a first clock signal, and the sink circuit is configured to receive a second clock signal different from the first clock signal, and the second clock signal is a clock signal delayed by a clock delay from the first clock signal, and the clock delay is determined based on a propagation delay margin.

### CROSS-REFERENCE TO RELATED APPLICATION

This application is based on and claims priority under 35 U.S.C. § 119 to Korean Patent Application No. 10-2024-0081372, filed on Jun. 21, 2024, in the Korean Intellectual Property Office, the disclosures of which are incorporated by reference herein in their entireties.

### BACKGROUND

One or more embodiments of the disclosure relate to a semiconductor memory, and more particularly, to a register clock driver and a memory module including the same.

Semiconductor memory devices are classified into volatile memory devices such as a static random-access memory (SRAM) and a dynamic random-access memory (DRAM), which lose stored data when power supply thereto is interrupted, and non-volatile memory devices such as a flash memory device, a phase change random access memory (PRAM), a magnetic random access memory (MRAM), a resistive random access memory (RRAM), and a ferroelectric random access memory (FRAM), which retain stored data even when power supply thereto is interrupted.

An operating frequency of a register clock driver has a wide frequency range. A propagation delay margin tPDM from an input to an output of a register clock driver is defined in the standard. A digital circuit is designed to be synchronized with a clock signal. A timing violation may occur in a data path in a high-speed frequency range. In the high-speed frequency range, a minimum standard propagation delay margin tPDM may not be satisfied. In a low-speed frequency range, a maximum propagation delay margin tPDM may not be satisfied. To resolve this, a register clock driver with a constant propagation delay margin independent of the operating frequency of the register clock driver is needed.

### SUMMARY

One or more embodiments of the disclosure provide a register clock driver having a constant propagation delay margin from an input to an output independent of an operating frequency of the register clock driver, and a memory module including the register clock driver.

According to an aspect of an example embodiment of the disclosure, there is provided a register clock driver including an input node configured to receive an input signal from a memory controller; an operating circuit configured to buffer the input signal and including a source circuit, a combination logic circuit, and a sink circuit, the source circuit including source flip-flops, and the sink circuit including sink flip-flops; and an output node configured to output an output signal to a memory device, wherein the source circuit is configured to receive a first clock signal, and the sink circuit is configured to receive a second clock signal different from the first clock signal, and wherein the second clock signal is a clock signal delayed by a clock delay from the first clock signal, and the clock delay is determined based on a propagation delay margin.

According to an aspect of an example of the disclosure, there is provided a memory module including a plurality of memory devices, each memory device of the plurality of memory devices including a memory cell array; and a register clock driver connected to the plurality of memory devices, wherein the register clock driver includes: an input node configured to receive a command/address signal from a memory controller; an output node configured to output an output command/address signal to the plurality of memory devices; and an operating circuit configured to buffer the command/address signal and including a source circuit, a combination logic circuit, and a sink circuit, the source circuit including source flip-flops, and the sink circuit including sink flip-flops, wherein each of the source flip-flops is configured to sample the command/address signal in response to a first clock signal of a first clock network, and each of the sink flip-flops is configured to sample a signal output from the combination logic circuit in response to a second clock signal of a second clock network, and wherein the second clock signal is a clock signal delayed by a clock delay from the first clock signal, and the clock delay is determined based on a propagation delay margin.

According to an aspect of an example of the disclosure, there is provided a register clock driver including an operating circuit configured to buffer a command/address signal and including a source circuit, a combination logic circuit, a sink circuit, and a clock delay circuit, the source circuit including source flip-flops, and the sink circuit including sink flip-flops; and a phased locked loop configured to receive a clock signal and generate a first clock signal based on the clock signal, wherein the clock delay circuit is configured to receive the first clock signal and generates a second clock signal by delaying the first clock signal by a clock delay, wherein each of the source flip-flops is configured to sample the command/address signal in response to the first clock signal of a first clock network and output the sampled command/address signal to the combination logic circuit, and wherein each of the sink flip-flops is configured to sample a signal output from the combination logic circuit and output the sampled signal in response to the second clock signal of a second clock network.

### BRIEF DESCRIPTION OF DRAWINGS

Embodiments of the disclosure will be more clearly understood from the following detailed description taken in conjunction with the accompanying diagrams, in which:

FIG. 1 is a block diagram of an electronic device according to one or more embodiments;

FIG. 2 is a block diagram showing a register clock driver (RCD) of FIG. 1 according to one or more embodiments;

FIG. 3 is a block diagram showing the RCD of FIG. 1 according to one or more embodiments;

FIG. 4 is a block diagram showing an operating circuit of FIG. 2 according to one or more embodiments;

FIG. 5A is a block diagram showing an example of a first clock network of FIG. 1;

FIG. 5B is a block diagram showing an example of a second clock network of FIG. 1;

FIG. 6 is a block diagram showing a clock delay circuit of FIG. 2 according to one or more embodiments;

FIG. 7 is a timing diagram to describe a propagation delay margin;

FIGS. 8A and 8B are timing diagrams illustrating an operation of an RCD;

FIGS. 9A and 9B are timing diagrams for describing an operation of the RCD of FIG. 1 according to one or more embodiments;

FIG. 10 is a block diagram showing the RCD of FIG. 1 according to one or more embodiments;

FIGS. 11 and 12 are block diagrams showing memory modules according to one or more embodiments, respectively;

FIG. 13 is a block diagram illustrating a computing system according to one or more embodiments;

FIG. 14 is a block diagram showing a computing system for designing an integrated circuit, according to one or more embodiments;

FIG. 15 is a flowchart of a method of designing an integrated circuit, according to one or more embodiments; and

FIG. 16 is a flowchart of a method of manufacturing an integrated circuit, according to one or more embodiments.

### DETAILED DESCRIPTION

Hereinafter, example embodiments of the disclosure will be described with reference to the attached drawings.

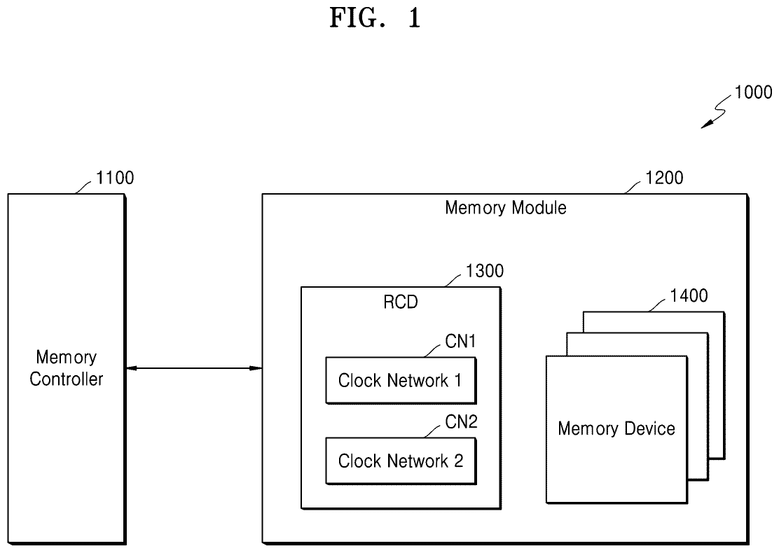

FIG. 1 is a block diagram of an electronic device according to one or more embodiments.

An electronic device 1000 may include a memory controller 1100 and a memory module 1200. For example, the electronic device 1000 may be one of various electronic devices, such as a desktop computer, a laptop computer, a workstation, a server, a mobile device, etc.

The memory controller 1100 may control the memory module 1200. The memory controller 1100 may perform data input and/or output with respect to the memory module 1200. The memory controller 1100 may be implemented in a host (not shown) and may access the memory module 1200 according to a request of a processor (not shown) within the host. For example, the memory controller 1100 may access the memory module 1200 in a direct memory access (DMA) manner. The memory controller 1100 may issue a command CMD and an address ADD (or a command/address (CA) signal) defined in the specifications of the memory module 1200 to the memory module 1200. In this specification, the term “CA” may refer to a command and/or an address or refer to command/address. For example, a CA signal may constitute a command or an address for accessing memory devices 1400.

The memory module 1200 may operate as a buffer memory, a working memory, and a main memory for the host including the memory controller 1100. The memory module 1200 may operate according to a command and an address issued by the memory controller 1100. The memory module 1200 may store data transmitted from the memory controller 1100 and/or transmit data to the memory controller 1100. The memory module 1200 may include a register clock driver (RCD) 1300 and the memory devices 1400. A number of RCDs 1300 and a number of memory devices 1400 are not limited to those shown in FIG. 1 and may each be at least one.

The RCD 1300 may be connected to one or more memory devices 1400. The RCD 1300 may drive the one or more memory devices 1400. The RCD 1300 may receive a clock signal CK, a chip select signal CS, and CA signals CA from the memory controller 1100 through a CA bus. The RCD 1300 may transmit the received clock signal CK, the received chip select signal CS, and the received CA signals CA to the memory devices 1400. The RCD 1300 may buffer the clock signal CK, the chip select signal CS, and the CA signals CA.

The memory devices 1400 may each perform data input/output requested by the memory controller 1100 based on the CA signals CA transmitted from the RCD 1300. The memory devices 1400 may each be referred to as a memory chip. The memory devices 1400 may each include a memory cell array. As described above, the number of memory devices 1400 that may be mounted on the memory module 1200 may be one or more. For example, a first memory device and a second memory device, which are identical to each other, may each receive the CA signals CA from the RCD 1300. In other words, the CA signals CA received by the first memory device and the CA signals CA received by the second memory device may be identical to each other.

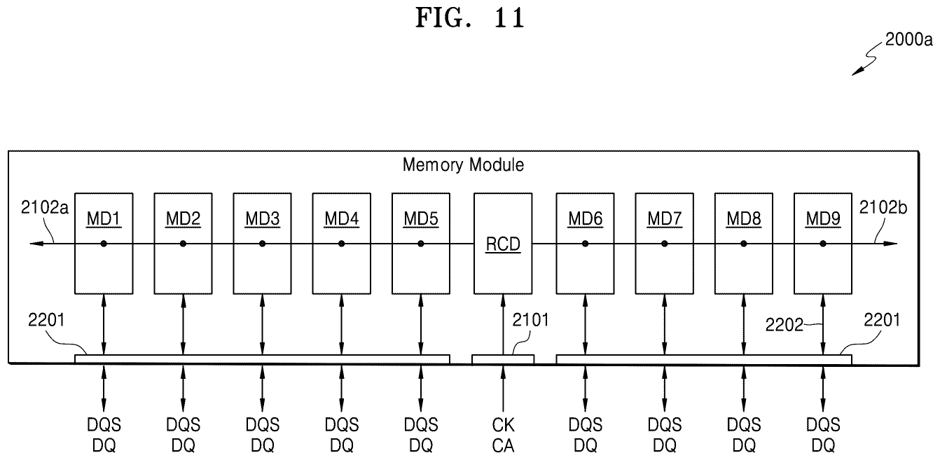

However, a first data input/output path of the first memory device may be different from a second data input/output path of the second memory device. The first memory device may perform data input/output with the memory controller 1100 through the first data input/output path (refer to FIG. 11) based on the CA signals CA. The second memory device may perform data input/output with the memory controller 1100 through the second data input/output path (refer to FIG. 11) based on the CA signals CA.

According to one or more embodiments, the memory device 1400 may be a dynamic random access memory (DRAM) device, a static random access memory (SRAM) device, a thyristor random access memory (TRAM) device, a NAND flash memory device, a NOR flash memory device, a resistive random access memory (RRAM) device, a ferroelectric random access memory (FRAM) device, a phase change random access memory (PRAM) device, a magnetic random access memory (MRAM) device, etc. The memory devices 1400 of one or more types may be mounted on the memory module 1200. The memory module 1200 may include one or more of a dual-inline memory module (DIMM), a registered DIMM (RDIMM), a load reduced DIMM (LRDIMM), and a non-volatile DIMM (NVDIMM) including the memory devices 1400 and the RCD 1300. Hereinafter, for illustrative purposes, it is assumed that the memory device 1400 is a DRAM device supporting a double data rate (DDR) interface.

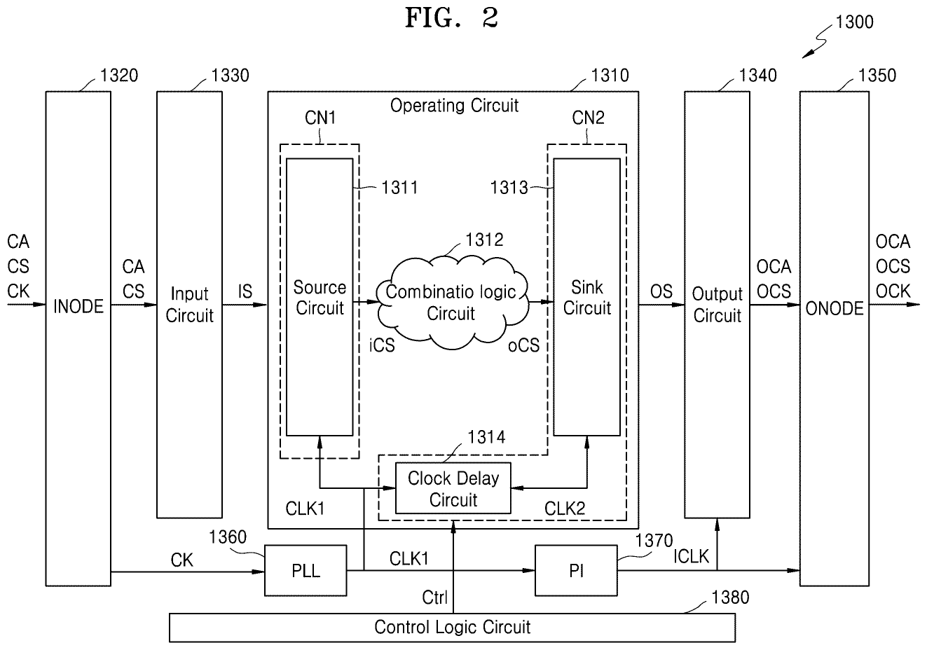

According to one or more embodiments, the RCD 1300 may include a plurality of clock networks (or clock distribution networks, clock trees, or clock domains). According to one or more embodiments, the RCD 1300 may include a first clock network CN1 and a second clock network CN2. For example, the RCD 1300 may be based on a multi-clock domain. A first clock domain CD1 may include a source circuit (1311 of FIG. 2) of an operating circuit (1310 of FIG. 2) of the RCD 1300, and a second clock domain CD2 may include a sink circuit (1313 of FIG. 2) of the operating circuit 1310 of the RCD 1300. The source circuit 1311 and the sink circuit 1313 may include different clock domains.

Typically, a source circuit and a sink circuit of an operating circuit of an RCD may receive the same clock signals. On the other hand, the source circuit 1311 according to one or more embodiments may receive a first clock signal (CLK1 of FIG. 2), and the sink circuit 1313 may receive a second clock signal (CLK2 of FIG. 2). The source circuit 1311 and the sink circuit 1313 may each have their own clock distribution network. Therefore, the RCD 1300 may have a constant propagation delay margin regardless of frequency changes. A layout of the operating circuit 1310 of the RCD 1300 may be designed in an auto place-and-routing (P&R) manner by using an automatic placement/routing tool. A stability and a reliability of an operation of the RCD 1300 may be improved. The operation and a configuration of the RCD 1300 according to the disclosure will be described below in more detail with reference to the drawings.

FIG. 2 is a block diagram showing the RCD of FIG. 1 according to one or more embodiments.

Referring to FIGS. 1 and 2, the RCD 1300 may include the operating circuit 1310, an input node 1320, an input circuit 1330, an output circuit 1340, an output node 1350, a phase locked loop (PLL) 1360, a phase interpolator 1370, and a control logic circuit 1380.

The RCD 1300 may receive the clock signal CK, the chip select signal CS, and the CA signals CA from the memory controller 1100 through the input node 1320 (e.g., an input pin). The input node 1320 may transmit the chip select signal CS and the CA signals CA to the input circuit 1330. The input node 1320 may transmit the clock signal CK to the PLL 1360.

The input circuit 1330 may receive the chip select signal CS and the CA signals CA through the input node 1320. The input circuit 1330 may buffer the CA signals CA and the chip select signal CS received through the input node 1320. Alternatively, the input circuit 1330 may sample the CA signals CA and the chip select signal CS received through the input node 1320. The input circuit 1330 may output a sampled chip select signal CS and sampled CA signals CA as input signals IS to the operating circuit 1310.

The operating circuit 1310 may receive the input signals IS from the input circuit 1330. The operating circuit 1310 may output output signals OS to the output circuit 1340. According to one or more embodiments, the operating circuit 1310 may include the source circuit 1311, a combination logic circuit 1312, the sink circuit 1313, and a clock delay circuit 1314.

The source circuit 1311 may receive the input signals IS from the input circuit 1330. The source circuit 1311 may receive the first clock signal CLK1 from the PLL 1360. The source circuit 1311 may sample the input signals IS in response to a first clock signal CLK1. The source circuit 1311 may output sampled input signals IS as an input combination signal iCS to the combination logic circuit 1312.

The combination logic circuit 1312 may be a digital logic circuit. The combination logic circuit 1312 may be implemented with a combination logic that performs a minimum function to match a standard propagation delay margin tPDM. The combination logic circuit 1312 may receive an input combination signal iCS. The combination logic circuit 1312 may perform a combination logic operation on the received input combination signal iCS. The combination logic circuit 1312 may output an output combination signal oCS, obtained based on the combination logic operation, to the sink circuit 1313.

The sink circuit 1313 may receive output combination signals oCS from the combination logic circuit 1312. The sink circuit 1313 may receive the second clock signal CLK2 from the clock delay circuit 1314. The sink circuit 1313 may sample the output combination signals oCS in response to the second clock signal CLK2. The sink circuit 1313 may output sampled output combination signals oCS as the output signals OS to the output circuit 1340.

The clock delay circuit 1314 may receive the first clock signal CLK1 from the PLL 1360. According to one or more embodiments, the clock delay circuit 1314 may include a delay chain including a plurality of inverters. The clock delay circuit 1314 may generate the second clock signal CLK2 by delaying the first clock signal CLK1 by a predetermined clock delay.

According to one or more embodiments, the clock delay circuit 1314 may receive a control signal Ctrl from the control logic circuit 1380. The clock delay circuit 1314 may generate the second clock signal CLK2, which is generated by delaying the first clock signal CLK1 by a clock delay, in response to the control signal Ctrl. The clock delay circuit 1314 may provide the second clock signal CLK2 to the sink circuit 1313.

The output circuit 1340 may receive the output signals OS from the operating circuit 1310. The output circuit 1340 may receive an interpolated clock signal ICLK from the phase interpolator 1370. The output circuit 1340 may generate output CA signals OCA and an output chip select signal OCS. The output circuit 1340 may sample the output signals OS in response to the interpolated clock signal ICLK. The output circuit 1340 may output sampled output signals OS as the output CA signals OCA and the output chip select signal OCS to the output node 1350. The output circuit 1340 may output sampled signals (output signals OS) as the output CA signals OCA to the memory devices 1400 through the output node 1350. The output circuit 1340 may output sampled signals (output signals OS) as the output chip select signal OCS to the memory devices 1400 through the output node 1350.

The RCD 1300 may output the output CA signals OCA, the output chip select signal OCS, and an output clock signal OCK to the memory devices 1400 through the output node 1350. The output node 1350 may transmit the output CA signals OCA, the output chip select signal OCS, and the output clock signal OCK to the memory devices 1400.

The PLL 1360 may receive the clock signal CK through the input node 1320. The PLL 1360 may generate the first clock signal CLK1. The PLL 1360 may provide the first clock signal CLK1 to the operating circuit 1310. The PLL 1360 may provide the first clock signal CLK1 to the phase interpolator 1370.

The phase interpolator 1370 may receive the first clock signal CLK1 from the PLL 1360. The phase interpolator 1370 may generate the interpolated clock signal ICLK by adjusting the phase of the first clock signal CLK1. The phase interpolator 1370 may output the interpolated clock signal ICLK to the output circuit 1340. The phase interpolator 1370 may output the interpolated clock signal ICLK as the output clock signal OCK to the memory devices 1400 through the output node 1350.

The control logic circuit 1380 may generate the control signal Ctrl and output the control signal control signal Ctrl to the clock delay circuit 1314. The control signal Ctrl may be a signal for controlling a clock delay. The control signal Ctrl may be a signal for selecting one of a plurality of intermediate clock signals iCLK.

As described above, the RCD 1300 may output the chip select signal CS and the CA signals CA to the memory devices 1400. The operating circuit 1310 may include a plurality of clock networks, that is, the first clock network CN1 and the second clock network CN2. Therefore, the RCD 1300 according to the disclosure may satisfy the propagation delay margin tPDM required by the standard.

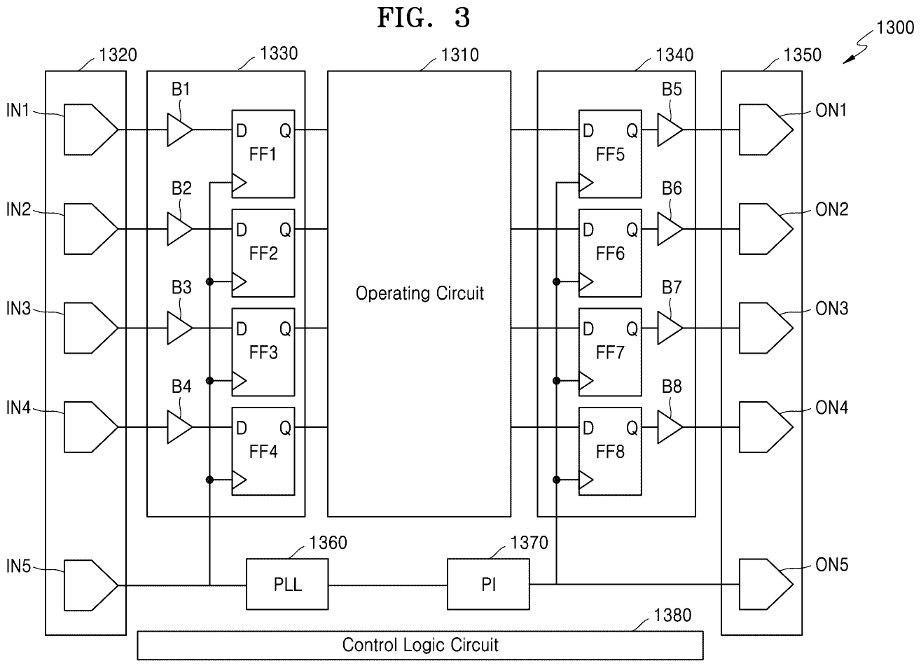

FIG. 3 is a block diagram showing the RCD 1300 of FIG. 1 according to one or more embodiments.

In the drawings below, for simplicity and convenience of explanation, it is assumed that the CA signals CA include first to third CA signals CA1 to CA3. However, the disclosure is not limited thereto. According to embodiments, the number of CA signals may be increased or decreased.

Referring to FIGS. 1, 2, and 3, the input node 1320 may include first to fifth input nodes IN1 to IN5. The input circuit 1330 may include first to fourth buffers B1 to B4 and first to fourth flip-flops FF1 to FF4. The output circuit 1340 may include fifth to eighth flip-flops FF5 to FF8 and fifth to eighth buffers B5 to B8. The output node 1350 may include first to fifth output nodes ON1 to ON5. However, the disclosure is not limited thereto, and, according to embodiments, a number of input nodes included in the input node 1320, a number of buffers included in the input circuit 1330, a number of flip-flops included in the input circuit 1330, a number of flip-flops included in the output circuit 1340, and a number of output nodes included in the output node 1350 may be reduced or increased.

The input node 1320 may transmit the CA signals CA and the chip select signal CS received from the memory controller 1100 to the input circuit 1330. The input node 1320 may transmit the clock signal CK received from the memory controller 1100 to the PLL 1360. A first input node IN1 may receive a first CA signal CA1 and transmit the first CA signal CA1 to a first buffer B1. A second input node IN2 may receive a second CA signal CA2 and transmit the second CA signal CA2 to a second buffer B2. A third input node IN3 may receive a third CA signal CA3 and transmit the third CA signal CA3 to a third buffer B3. A fourth input node IN4 may receive the chip select signal CS and transmit the chip select signal CS to a fourth buffer B4. A fifth input node IN5 may receive the clock signal CK and transmit the clock signal CK to the PLL 1360.

The input circuit 1330 may receive the chip select signal CS and the CA signals CA and output the input signal IS to the operating circuit 1310. For example, the first buffer B1 may buffer the first CA signal CA1 received through the first input node IN1. The first buffer B1 may output the first CA signal CA1 to a first flip-flop FF1. The second buffer B2 may buffer the second CA signal CA2 received through the second input node IN2. The second buffer B2 may output the second CA signal CA2 to a second flip-flop FF2. The third buffer B3 may buffer the third CA signal CA3 received through the third input node IN3. The third buffer B3 may output the third CA signal CA3 to a third flip-flop FF3. The fourth buffer B4 may buffer the chip select signal CS received through the fourth input node IN4. The fourth buffer B4 may output the chip select signal CS to a fourth flip-flop FF4.

For example, the first flip-flop FF1 may include a clock input terminal, an input terminal D, and an output terminal Q. The first flip-flop FF1 may receive the clock signal CK through the clock input terminal, receive the first CA signal CA1 through the input terminal D, and output a first input signal IS1 through the output terminal Q. The first flip-flop FF1 may operate in response to the clock signal CK. The first flip-flop FF1 may sample the first CA signal CA1 in response to the clock signal CK. The first flip-flop FF1 may output a sampled signal as the first input signal IS1. The first flip-flop FF1 may output a logic level (e.g., logic high or logic low) of the first CA signal CA1 as the first input signal IS1 through the output terminal Q in response to a rising edge of the clock signal CK. The first flip-flop FF1 may transmit the first input signal IS1 to the operating circuit 1310.

The second flip-flop FF2 may include a clock input terminal, an input terminal D, and an output terminal Q. The second flip-flop FF2 may receive the clock signal CK through the clock input terminal, receive the second CA signal CA2 through the input terminal D, and output a second input signal IS2 through the output terminal Q. The second flip-flop FF2 may operate in response to the clock signal CK. The second flip-flop FF2 may sample the second CA signal CA2 in response to the clock signal CK. The second flip-flop FF2 may output a sampled signal as the second input signal IS2. The second flip-flop FF2 may output a logic level of the second CA signal CA2 as the second input signal IS2 through the output terminal Q in response to the rising edge of the clock signal CK. The second flip-flop FF2 may transmit the second input signal IS2 to the operating circuit 1310.

The third flip-flop FF3 may include a clock input terminal, an input terminal D, and an output terminal Q. The third flip-flop FF3 may receive the clock signal CK through the clock input terminal, receive the third CA signal CA3 through the input terminal D, and output a third input signal IS3 through the output terminal Q. The third flip-flop FF3 may operate in response to the clock signal CK. The third flip-flop FF3 may sample the third CA signal CA3 in response to the clock signal CK. The third flip-flop FF3 may output a sampled signal as the third input signal IS3. The third flip-flop FF3 may output a logic level of the third CA signal CA3 as the third input signal IS3 through the output terminal Q in response to the rising edge of the clock signal CK. The third flip-flop FF3 may transmit the third input signal IS3 to the operating circuit 1310.

The fourth flip-flop FF4 may include a clock input terminal, an input terminal D, and an output terminal Q. The fourth flip-flop FF4 may receive the clock signal CK through the clock input terminal, receive the chip select signal CS through the input terminal D, and output a fourth input signal IS4 through the output terminal Q. The fourth flip-flop FF4 may operate in response to the clock signal CK. The fourth flip-flop FF4 may sample the chip select signal CS in response to the clock signal CK. The fourth flip-flop FF4 may output a sampled signal as the fourth input signal IS4. The fourth flip-flop FF4 may output a logic level of the chip select signal CS as the fourth input signal IS4 through the output terminal Q in response to the rising edge of the clock signal CK. The fourth flip-flop FF4 may transmit the fourth input signal IS4 to the operating circuit 1310.

The operating circuit 1310 may receive input signals IS or IS1 to IS4 from the input circuit 1330 and output output signals OS or OS1 to OS4 to the output circuit 1340. The operating circuit 1310 may include a buffer configured to transmit the chip select signals CS and the CA signals CA of the memory controller 1100 to the memory devices 1400. The memory devices 1400 may receive the clock signal CK and the CA signals CA from the memory controller 1100 through the operating circuit 1310 of the RCD 1300. The memory devices 1400 may not receive the clock signal CK and the CA signals CA from the memory controller 1100. The operating circuit 1310 may improve a signal integrity (SI) of the clock signal CK and the CA signals CA received from the memory controller 1100 to the memory devices 1400.

The output circuit 1340 may receive the output signals OS and the interpolated clock signal ICLK and output the output CA signals OCA and the output chip select signal oCS. For example, a fifth flip-flop FF5 may include a clock input terminal, an input terminal D, and an output terminal Q. The fifth flip-flop FF5 may receive the interpolated clock signal ICLK from the phase interpolator PI 1370 through the clock input terminal, receive a first output signal OS1 through an input terminal D, and output a first output CA signal OCA1 through the output terminal Q. The fifth flip-flop FF5 may operate in response to the interpolated clock signal ICLK. The fifth flip-flop FF5 may sample the first output signal OS1 in response to the interpolated clock signal ICLK. The fifth flip-flop FF5 may output a sampled signal as the first output CA signal OCA1. The fifth flip-flop FF5 may output the logic level of the first output signal OS1 as the first output CA signal OCA1 through the output terminal Q in response to a rising edge of the interpolated clock signal ICLK. The fifth flip-flop FF5 may output the first output CA signal OCA1 to a fifth buffer B5.

A sixth flip-flop FF6 may include a clock input terminal, an input terminal D, and an output terminal Q. The sixth flip-flop FF6 may receive the interpolated clock signal ICLK from the phase interpolator PI 1370 through the clock input terminal, receive a second output signal OS2 through an input terminal D, and output a second output CA signal OCA2 through the output terminal Q. The sixth flip-flop FF6 may operate in response to the interpolated clock signal ICLK. The sixth flip-flop FF6 may sample the second output signal OS2 in response to the interpolated clock signal ICLK. The sixth flip-flop FF6 may output a sampled signal as the second output CA signal OCA2. The sixth flip-flop FF6 may output a logic level of the second output signal OS2 as the second output CA signal OCA2 through the output terminal Q in response to the rising edge of the interpolated clock signal ICLK. The sixth flip-flop FF6 may output the second output CA signal OCA2 to a sixth buffer B6.

A seventh flip-flop FF7 may include a clock input terminal, an input terminal D, and an output terminal Q. The seventh flip-flop FF7 may receive the interpolated clock signal ICLK from the phase interpolator PI 1370 through the clock input terminal, receive a third output signal OS3 through an input terminal D, and output a third output CA signal OCA3 through the output terminal Q. The seventh flip-flop FF7 may operate in response to the interpolated clock signal ICLK. The seventh flip-flop FF7 may sample the third output signal OS3 in response to the interpolated clock signal ICLK. The seventh flip-flop FF7 may output a sampled signal as the third output CA signal OCA3. The seventh flip-flop FF7 may output a logic level of the third output signal OS3 as the third output CA signal OCA3 through the output terminal Q in response to the rising edge of the interpolated clock signal ICLK. The seventh flip-flop FF7 may output the third output CA signal OCA3 to a seventh buffer B7.

An eighth flip-flop FF8 may include a clock input terminal, an input terminal D, and an output terminal Q. The eighth flip-flop FF8 may receive the interpolated clock signal ICLK from the phase interpolator PI 1370 through the clock input terminal, receive a fourth output signal OS4 through an input terminal D, and output a fourth output CA signal OCA4 through the output terminal Q. The eighth flip-flop FF8 may operate in response to the interpolated clock signal ICLK. The eighth flip-flop FF8 may sample the fourth output signal OS4 in response to the interpolated clock signal ICLK. The eighth flip-flop FF8 may output a sampled signal as the output chip select signal OCS. The eighth flip-flop FF8 may output a logic level of the fourth output signal OS4 as the output chip select signal OCS through the output terminal Q in response to the rising edge of the interpolated clock signal ICLK. The eighth flip-flop FF8 may output the output chip select signal OCS to an eighth buffer B8.

For example, the fifth buffer B5 may buffer the received first output CA signal OCA1. The first buffer B1 may output the first output CA signal OCA1 to a first output node ON1. The second buffer B2 may buffer the received second output CA signal OCA2. The second buffer B2 may output the second output CA signal OCA2 to a second output node ON2. The third buffer B3 may buffer the received third output CA signal OCA3. The third buffer B3 may output the third output CA signal OCA3 to a third output node ON3. The fourth buffer B4 may buffer the received output chip select signal OCS. The fourth buffer B4 may output the output chip select signal OCS to a fourth output node ON4.

The phase interpolator 1370 may output the interpolated clock signal ICLK to a fifth output node ON5. The output node 1350 may transmit the output CA signals OCA, the output chip select signal OCS, and the interpolated clock signal ICLK (e.g., the output clock signal OCK) received from the output circuit 1340 and the phase interpolator 1370 to the memory devices 1400. The first output node ON1 may receive the first output CA signal OCA1 from the fifth buffer B5 and transmit the first output CA signal OCA1 to the memory devices 1400. The second output node ON2 may receive the second output CA signal OCA2 from the sixth buffer B6 and transmit the second output CA signal OCA2 to the memory devices 1400. The third output node ON3 may receive the third output CA signal OCA3 from the seventh buffer B7 and transmit the third output CA signal OCA3 to the memory devices 1400. The fourth output node ON4 may receive an output chip select signal OCS from the fourth buffer B4 and transmit the output chip select signal OCS to the memory devices 1400. The fifth output node ON5 may receive the output clock signal OCK from the phase interpolator PI 1370 and transmit the output clock signal OCK to the memory devices 1400.

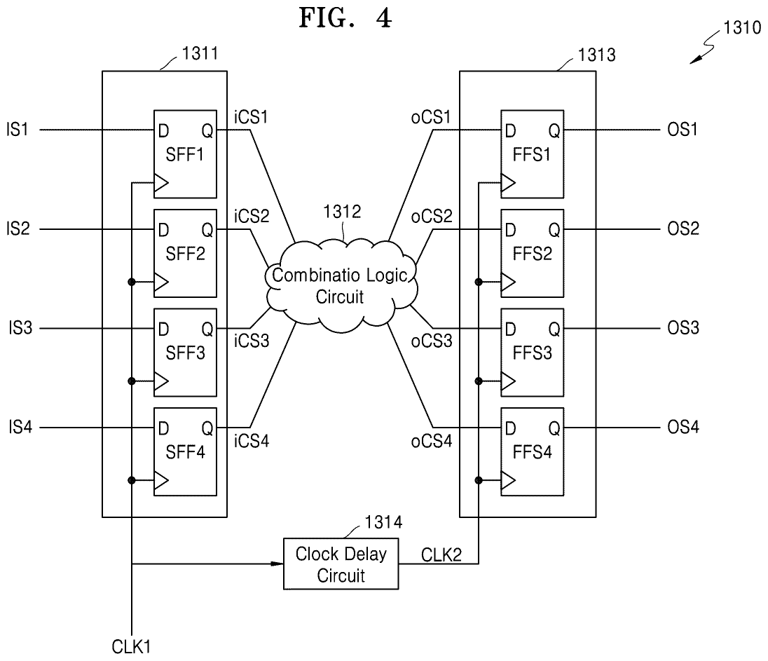

FIG. 4 is a block diagram showing the operating circuit 1310 of FIG. 2 according to one or more embodiments.

Referring to FIGS. 1, 2, and 4, the operating circuit 1310 may include the source circuit 1311, the combination logic circuit 1312, the sink circuit 1313, and the clock delay circuit 1314. The source circuit 1311 may be included in the first clock domain CD1, and the sink circuit 1313 may be included in the second clock domain CD2.

The source circuit 1311 may include first to fourth source flip-flops SFF1 to SFF4. The source circuit 1311 may receive first to fourth input signals IS1 to IS4 and the first clock signal CLK1. For example, a first source flip-flop SFF1 may include a clock input terminal, an input terminal D, and an output terminal Q. The first source flip-flop SFF1 may receive the first clock signal CLK1 from the PLL 1360 through the clock input terminal, receive the first input signal IS1 through the input terminal D, and output a first input combination signal iCS1 through the output terminal Q. The first source flip-flop SFF1 may operate in response to the first clock signal CLK1. The first source flip-flop SFF1 may sample the first input signal IS1 in response to the first clock signal CLK1. The first source flip-flop SFF1 may output a sampled signal as the first input combination signal iCS1. The first source flip-flop SFF1 may output a logic level of the first input signal IS1 as the first input combination signal iCS1 through the output terminal Q in response to a rising edge of the first clock signal CLK1. The first source flip-flop SFF1 may output the first input combination signal iCS1 to the combination logic circuit 1312.

A second source flip-flop SFF2 may include a clock input terminal, an input terminal D, and an output terminal Q. The second source flip-flop SFF2 may receive the first clock signal CLK1 from the PLL 1360 through the clock input terminal, receive the second input signal IS2 through the input terminal D, and output a second input combination signal iCS2 through the output terminal Q. The second source flip-flop SFF2 may operate in response to the first clock signal CLK1. The second source flip-flop SFF2 may sample the second input signal IS2 in response to the first clock signal CLK1. The second source flip-flop SFF2 may output a sampled signal as the second input combination signal iCS2. The second source flip-flop SFF2 may output a logic level of the second input signal IS2 as the second input combination signal iCS2 through the output terminal Q in response to the rising edge of the first clock signal CLK1. The second source flip-flop SFF2 may output the second input combination signal iCS2 to the combination logic circuit 1312.

A third source flip-flop SFF3 may include a clock input terminal, an input terminal D, and an output terminal Q. The third source flip-flop SFF3 may receive the first clock signal CLK1 from the PLL 1360 through the clock input terminal, receive the third input signal IS3 through the input terminal D, and output a third input combination signal iCS3 through the output terminal Q. The third source flip-flop SFF3 may operate in response to the first clock signal CLK1. The third source flip-flop SFF3 may sample the third input signal IS3 in response to the first clock signal CLK1. The third source flip-flop SFF3 may output a sampled signal as the third input combination signal iCS3. The third source flip-flop SFF3 may output a logic level of the third input signal IS3 as the third input combination signal iCS3 through the output terminal Q in response to the rising edge of the first clock signal CLK1. The third source flip-flop SFF3 may output the third input combination signal iCS3 to the combination logic circuit 1312.

A fourth source flip-flop SFF4 may include a clock input terminal, an input terminal D, and an output terminal Q. The fourth source flip-flop SFF4 may receive the first clock signal CLK1 from the PLL 1360 through the clock input terminal, receive the fourth input signal IS4 through the input terminal D, and output a fourth input combination signal iCS4 through the output terminal Q. The fourth source flip-flop SFF4 may operate in response to the first clock signal CLK1. The fourth source flip-flop SFF4 may sample the fourth input signal IS4 in response to the first clock signal CLK1. The fourth source flip-flop SFF4 may output a sampled signal as the fourth input combination signal iCS4. The fourth source flip-flop SFF4 may output a logic level of the fourth input signal IS4 as the fourth input combination signal iCS4 through the output terminal Q in response to the rising edge of the first clock signal CLK1. The fourth source flip-flop SFF4 may output the fourth input combination signal iCS4 to the combination logic circuit 1312.

The sink circuit 1313 may include first to fourth sink flip-flops FFS1 to FFS4. The sink circuit 1313 may receive first to fourth output combination signals oCS1 to oCS4 and the second clock signal CLK2. A first sink flip-flop FFS1 may include a clock input terminal, an input terminal D, and an output terminal Q. The first sink flip-flop FFS1 may receive the second clock signal CLK2 from the clock delay circuit 1314 through the clock input terminal, receive a first output combination signal oCS1 through the input terminal D, and output, as the first output signal OS1, the first output CA signal OCA1 through the output terminal Q. The first sink flip-flop FFS1 may operate in response to the second clock signal CLK2. The first sink flip-flop FFS1 may sample the first output combination signal oCS1 in response to the second clock signal CLK2. The first sink flip-flop FFS1 may output a sampled signal as the first output CA signal OCA1. The first sink flip-flop FFS1 may output a logic level of the first output combination signal oCS1 as the first output CA signal OCA1 through the output terminal Q in response to a rising edge of the second clock signal CLK2. The first sink flip-flop FFS1 may output, as the first output signal OS1, the first output CA signal OCA1 to the first output node ON1.

A second sink flip-flop FFS2 may include a clock input terminal, an input terminal D, and an output terminal Q. The second sink flip-flop FFS2 may receive the second clock signal CLK2 from the clock delay circuit 1314 through the clock input terminal, receive a second output combination signal oCS2 through the input terminal D, and output, as the second output signal OS2, the second output CA signal OCA2 through the output terminal Q. The second sink flip-flop FFS2 may operate in response to the second clock signal CLK2. The second sink flip-flop FFS2 may sample the second output combination signal oCS2 in response to the second clock signal CLK2. The second sink flip-flop FFS2 may output a sampled signal as the second output CA signal OCA2. The second sink flip-flop FFS2 may output a logic level of the second output combination signal oCS2 as the second output CA signal OCA2 through the output terminal Q in response to the rising edge of the second clock signal CLK2. The second sink flip-flop FFS2 may output, as the second output signal OS2, the second output CA signal OCA2 to the second output node ON2.

A third sink flip-flop FFS3 may include a clock input terminal, an input terminal D, and an output terminal Q. The third sink flip-flop FFS3 may receive the second clock signal CLK2 from the clock delay circuit 1314 through the clock input terminal, receive a third output combination signal oCS3 through the input terminal D, and output, as the third output signal OS3, the third output CA signal OCA3 through the output terminal Q. The third sink flip-flop FFS3 may operate in response to the second clock signal CLK2. The third sink flip-flop FFS3 may sample the third output combination signal oCS3 in response to the second clock signal CLK2. The third sink flip-flop FFS3 may output a sampled signal as the third output CA signal OCA3. The third sink flip-flop FFS3 may output a logic level of the third output combination signal oCS3 as the third output CA signal OCA3 through the output terminal Q in response to the rising edge of the second clock signal CLK2. The third sink flip-flop FFS3 may output, as the third output signal OS3, the third output CA signal OCA3 to the third output node ON3.

A fourth sink flip-flop FFS4 may include a clock input terminal, an input terminal D, and an output terminal Q. The fourth sink flip-flop FFS4 may receive the second clock signal CLK2 from the clock delay circuit 1314 through the clock input terminal, receive a fourth output combination signal oCS4 through the input terminal D, and output, as the fourth output signal OS4, the output chip select signal OCS through the output terminal Q. The fourth sink flip-flop FFS4 may operate in response to the second clock signal CLK2. The fourth sink flip-flop FFS4 may sample the fourth output combination signal oCS4 in response to the second clock signal CLK2. The fourth sink flip-flop FFS4 may output a sampled signal as the output chip select signal OCS. The fourth sink flip-flop FFS4 may output a logic level of the fourth output combination signal oCS4 as the output chip select signal OCS through the output terminal Q in response to the rising edge of the second clock signal CLK2. The fourth sink flip-flop FFS4 may output, as the fourth output signal OS4, the output chip select signal OCS to the fourth output node ON4.

As described above, the operating circuit 1310 may include a plurality of clock networks. The source circuit 1311 may receive the first clock signal CLK1, and the sink circuit 1313 may receive the second clock signal CLK2. The operating circuit 1310 may include the first clock network CN1 and the second clock network CN2. The operating circuit 1310 may be based on a multi-clock domain.

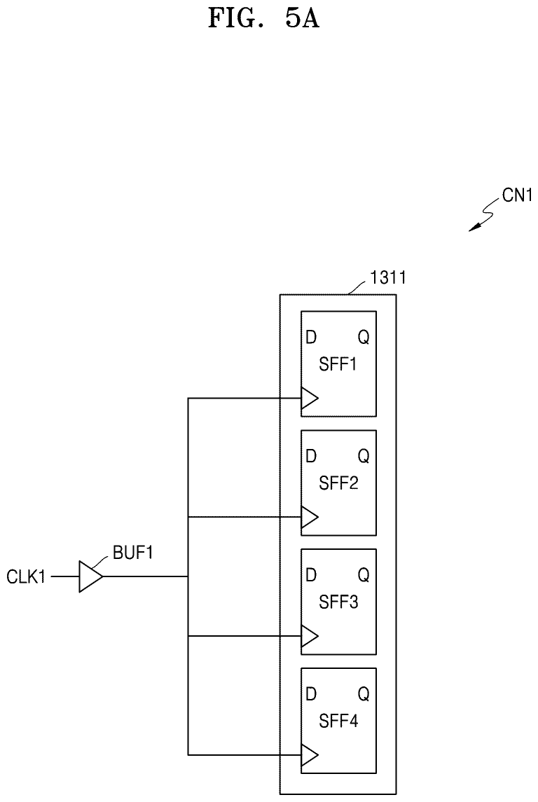

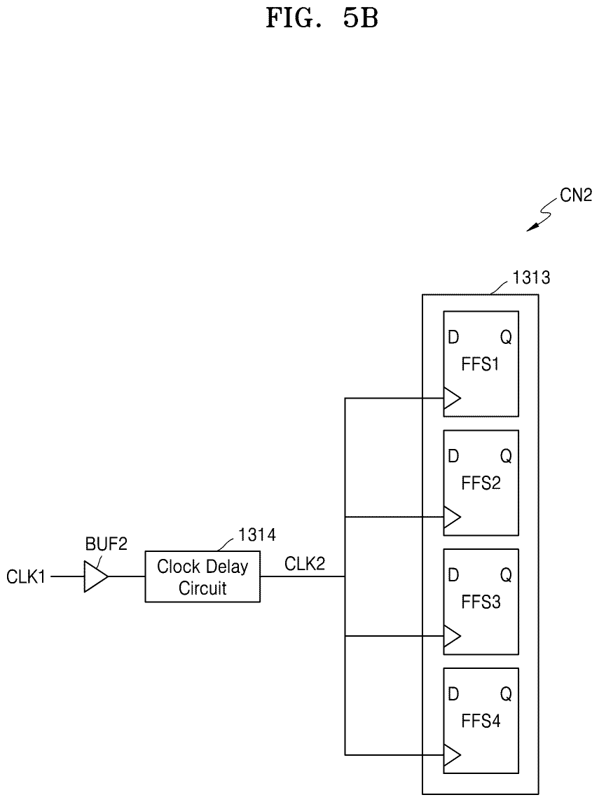

FIG. 5A is a block diagram showing an example of a first clock network of FIG. 1. FIG. 5B is a block diagram showing an example of a second clock network of FIG. 1.

Referring to FIGS. 1, 2, 5A, and 5B, the operating circuit 1310 may include the first clock network CN1 and the second clock network CN2. The source circuit 1311 and the sink circuit 1313 may be included in different clock networks. The source circuit 1311 may be included in the first clock network CN1, and the sink circuit 1313 may be included in the second clock network CN2. In the same clock network, clock signals may reach all flip-flops at the same or similar time points.

The first clock network CN1 may include a first buffer BUF1 and the source circuit 1311. The first clock network CN1 may include the first buffer BUF1 and a plurality of source flip-flops, e.g., the first to fourth source flip-flops SFF1 to SFF4. A root of the first clock network CN1 may be the first clock signal CLK1. Leaves (or edges) of the first clock network CN1 may be the first to fourth source flip-flops SFF1 to SFF4. The first buffer BUF1 may receive the first clock signal CLK1. The first buffer BUF1 may buffer the first clock signal CLK1. The first buffer BUF1 may provide a buffered first clock signal CLK1 to the first to fourth source flip-flops SFF1 to SFF4.

The second clock network CN2 may include a second buffer BUF2, the clock delay circuit 1314, and the sink circuit 1313. The second clock network CN2 may include the second buffer BUF2, the clock delay circuit 1314, and a plurality of sink flip-flops, e.g., first to fourth sink flip-flops FFS1 to FFS4. A root of the second clock network CN2 may be the first clock signal CLK1. The root of the second clock network CN2 may be identical to the root of the first clock network CN1. However, the second clock network CN2 may have a clock network latency different from that of the first clock network CN1. The difference between clock network latencies of the first clock network CN1 and the second clock network CN2 may correspond to a clock delay (e.g., logic propagation delay margin tPDM_LOGIC).

Leaves (or edges) of the second clock network CN2 may be the first to fourth sink flip-flops FFS1 to FFS4. The second buffer BUF2 may receive the first clock signal CLK1. The second buffer BUF2 may buffer the first clock signal CLK1. The second buffer BUF2 may output a buffered first clock signal CLK1 to the clock delay circuit 1314.

The clock delay circuit 1314 may generate the second clock signal CLK2 based on the first clock signal CLK1. The clock delay circuit 1314 may generate the second clock signal CLK2 delayed by the clock delay from the first clock signal CLK1. The clock delay circuit 1314 may provide the second clock signal CLK2 to the first to fourth sink flip-flops FFS1 to FFS4.

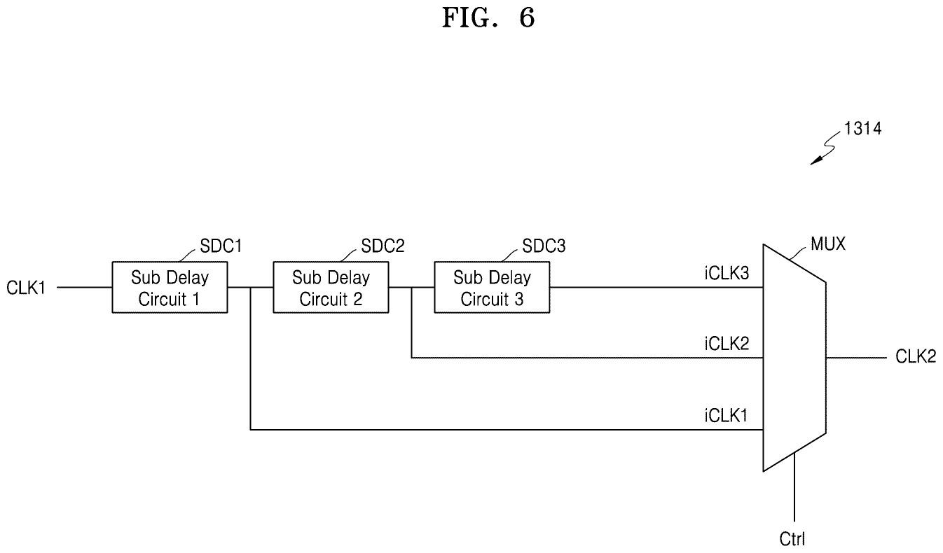

FIG. 6 is a block diagram showing the clock delay circuit 1314 of FIG. 2 according to one or more embodiments.

Referring to FIGS. 2 and 6, the clock delay circuit 1314 may include first to third sub-delay circuits SDC1 to SDC3 and a multiplexer MUX. However, the disclosure is not limited thereto, and a number of sub-delay circuits may be increased or decreased according to embodiments. For example, the first to third sub-delay circuits SDC1 to SDC3 may each include a delay chain including a plurality of inverters. Alternatively, the first to third sub-delay circuits SDC1 to SDC3 may each include various types of delays other than an inverter delay.

The clock delay circuit 1314 may receive the first clock signal CLK1 and the control signal Ctrl. The clock delay circuit 1314 may generate the second clock signal CLK2. The clock delay circuit 1314 may generate the second clock signal CLK2 delayed by the clock delay from the first clock signal CLK1. The clock delay circuit 1314 may generate the second clock signal CLK2 based on the first clock signal CLK1 and the control signal Ctrl. The clock delay circuit 1314 may output the second clock signal CLK2. The clock delay circuit 1314 may adjust the clock delay based on the control signal Ctrl.

A first sub-delay circuit SDC1 may receive the first clock signal CLK1. The first sub-delay circuit SDC1 may generate a first intermediate clock signal iCLK1 delayed by a first sub-delay from the first clock signal CLK1. The first sub-delay circuit SDC1 may output the first intermediate clock signal iCLK1 to a second sub-delay circuit SDC2. The first sub-delay circuit SDC1 may output the first intermediate clock signal iCLK1 to the multiplexer MUX.

The second sub-delay circuit SDC2 may receive the first intermediate clock signal iCLK1. The second sub-delay circuit SDC2 may generate a second intermediate clock signal iCLK2 delayed by a second sub-delay from the first intermediate clock signal iCLK1. The second sub-delay circuit SDC2 may output the second intermediate clock signal iCLK2 to a third sub-delay circuit SDC3. The second sub-delay circuit SDC2 may output the second intermediate clock signal iCLK2 to the multiplexer MUX. The second intermediate clock signal iCLK2 may be a clock signal delayed by a sum of the first sub-delay and the second sub-delay from the first clock signal CLK1.

The third sub-delay circuit SDC3 may receive the second intermediate clock signal iCLK2. The third sub-delay circuit SDC3 may generate a third intermediate clock signal iCLK3 delayed by a third sub-delay from the second intermediate clock signal iCLK2. The third sub-delay circuit SDC3 may output the third intermediate clock signal iCLK3 to the multiplexer MUX. The third intermediate clock signal iCLK3 may be a clock signal delayed by a sum of the first sub-delay, the second sub-delay, and the third sub-delay from the first clock signal CLK1.

The multiplexer MUX may receive the first intermediate clock signal iCLK1 from the first sub-delay circuit SDC1, the second intermediate clock signal iCLK2 from the second sub-delay circuit SDC2, the third intermediate clock signal iCLK3 from the third sub-delay circuit SDC3, and the control signal Ctrl from the control logic circuit 1328. The multiplexer MUX may select any one of first to third intermediate clock signals iCLK1 to iCLK3 based on the control signal Ctrl and output a selected signal as the second clock signal CLK2 to the sink circuit 1313.

As described above, the clock delay circuit 1314 may select one of a plurality of intermediate clock signals, e.g., the first to third intermediate control signals iCLK1 to iCLK3, based on the control signal Ctrl and output a selected signal as the second clock signal CLK2. The clock delay circuit 1314 may adjust the clock delay based on the control signal Ctrl. The clock delay circuit 1314 may adjust the clock delay based on the control signal Ctrl finely or coarsely. Therefore, the RCD 1300 may adjust the clock delay in response to various factors such as a change in a design specification, a design issue of the operating circuit 1310 (e.g., a component characteristic, a differences between physical lengths of lines (or tracks), etc.), a process-voltage-temperature (PVT) variation, etc.

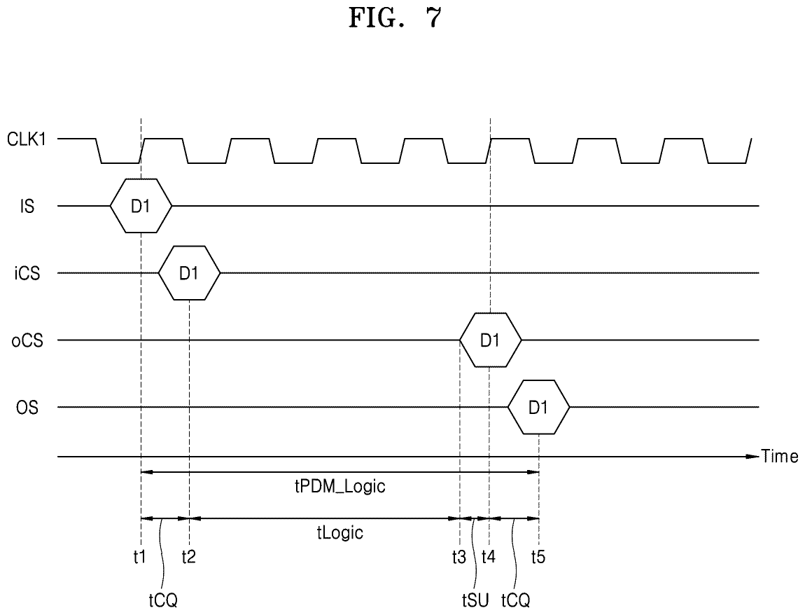

FIG. 7 is a timing diagram to describe a propagation delay margin.

The propagation delay margin tPDM will be described with reference to FIG. 7. For convenience of explanation, it will be assumed that the source circuit 1311 receives the first clock signal CLK1, and the sink circuit 1313 also receives the first clock signal CLK1.

Referring to FIG. 2 and FIG. 7, the propagation delay margin tPDM refers to a propagation delay margin between the input and the output of the RCD 1300 required by the standard. The logic propagation delay margin tPDM_LOGIC refers to a time obtained by subtracting the propagation delay margin of the input circuit 1330 and the propagation delay margin of the output circuit 1340 from the propagation delay margin tPDM. The logic propagation delay margin tPDM_LOGIC may refer to the propagation delay margin of the operating circuit 1310.

The logic propagation delay margin tPDM_LOGIC may be defined by Equation 1 as expressed below. Here, tCQ may denote a clock-output delay, tSU may denote a setup time, and tLOGIC may denote the propagation delay margin of the combination logic circuit 1312.

$$tPDM\_LOGIC = tCQ + tLOGIC + tSU + tCQ \qquad [ Equation 1 ]$$

The setup time tSU refers to a time needed to stably provide data of an input signal received at an input terminal. In other words, the setup time tSU refers to a time during which transition of an input signal needs to be completed before a sampling edge of a clock signal. The clock-output delay tCQ refers to a delay until data of the input signal synchronized to the sampling edge of the clock signal is output as an output signal.

At a first time point t1, the first clock signal CLK1 may rise (or transition) from a logic low level to a logic high level. At the first time point t1, a source flip-flop SFF may sample first data D1 of the input signal IS in response to the rising edge of the first clock signal CLK1. At a second time point t2, the source flip-flop SFF may output first data D1 of the input combination signal iCS through the output terminal Q.

At a third time point t3, the combination logic circuit 1312 may output first data D1 of the output combination signal oCS. At the third time point t3, the output combination signal oCS may transition to the first data D1. At a fourth time point t4, the first clock signal CLK1 may rise from a logic-low level to a logic-high level. At the fourth time point t4, a sink flip-flop FFS may sample the first data D1 of the output combination signal oCS. At a fifth time point t5, the sink flip-flop FFS may output first data D1 of the output signal OS through the output terminal Q.

The time period from the first time point t1 to the second time point t2 may correspond to the clock-output delay tCQ of the source flip-flop SFF. The time period from the second time point t2 to the third time point t3 may correspond to the logic delay tLOGIC. The time period from the third time point t3 to the fourth time point t4 may correspond to the setup time tSU of the sink flip-flop FFS. The time period from the fourth time point t4 to the fifth time point t5 may correspond to the clock-output delay tCQ of the sink flip-flop FFS.

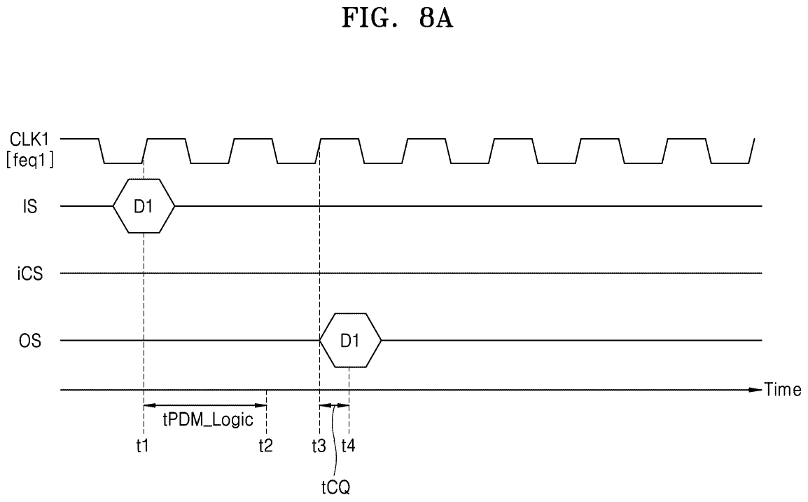

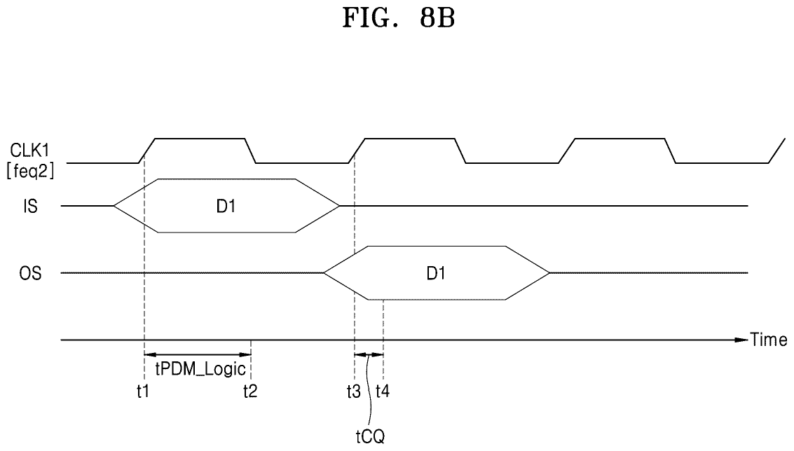

FIGS. 8A and 8B are timing diagrams illustrating an operation of an RCD.

For convenience of explanation, it will be assumed that the source circuit 1311 receives the first clock signal CLK1, and the sink circuit 1313 also receives the first clock signal CLK1. FIG. 8A shows a case where the operating circuit 1310 receives the first clock signal CLK1 of a first frequency feq1 (e.g., a high frequency), and FIG. 8B shows a case where the operating circuit 1310 receives the first clock signal CLK1 of a second frequency feq2 (e.g., a low frequency). The first frequency feq1 may refer to a maximum frequency required by the standard, and the second frequency feq2 may refer to a minimum frequency required by the standard. The logic propagation delay margin tPDM_LOGIC may be longer than a period of the first clock signal CLK1 of the first frequency feq1 and shorter than a period of the first clock signal CLK1 of the second frequency feq2.

Referring to FIG. 8A, at a first time point t1, the first clock signal CLK1 may rise from a logic low level to a logic high level. At the first time point t1, a source flip-flop SFF may sample first data D1 of the input signal IS in response to the rising edge of the first clock signal CLK1. Since the logic propagation delay margin tPDM_LOGIC is longer than the period of the first clock signal CLK1 of the first frequency feq1, the combination logic circuit 1312 may output first data D1 of the output combination signal oCS after a second time point t2. At a third time point t3, the first clock signal CLK1 may rise from a logic low level. At the third time point t3, the sink flip-flop FFS may sample the first data D1 of the output combination signal oCS in response to the rising edge of the first clock signal CLK1. The sink flip-flop FFS may output first data D1 of the output signal OS through the output terminal Q at a fourth time point t4, which is the clock-output delay tCQ after the third time point t3. Therefore, since the output signal OS is output after the second time point t2, the RCD 1300 may satisfy the propagation delay margin tPDM required by the standard.

Referring to FIG. 8B, at a first time point t1, the first clock signal CLK1 may rise from a logic low level to a logic high level. At the first time point t1, a source flip-flop SFF may sample first data D1 of the input signal IS in response to the rising edge of the first clock signal CLK1. The combination logic circuit 1312 may output first data D1 of the output combination signal oCS after a second time point t2. However, since the period of the first clock signal CLK1 of the second frequency feq2 is longer than the logic propagation delay margin tPDM_LOGIC, the sink flip-flop FFS may sample the first data D1 of the output combination signal oCS at a third time point t3. In other words, at the third time point t3 after the second time point t2, the first clock signal CLK1 may rise from a logic low level. At the third time point t3, the sink flip-flop FFS may sample the first data D1 of the output combination signal oCS in response to the rising edge of the first clock signal CLK1. The sink flip-flop FFS may output first data D1 of the output signal OS through the output terminal Q at a fourth time point t4, which is the clock-output delay tCQ after the third time point t3. Therefore, since the output signal OS is output after the second time point t2, the RCD 1300 may satisfy the propagation delay margin tPDM required by the standard.

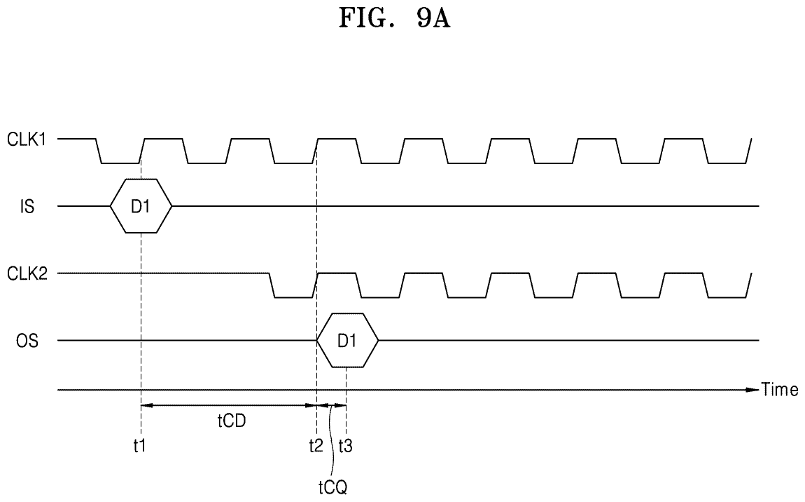

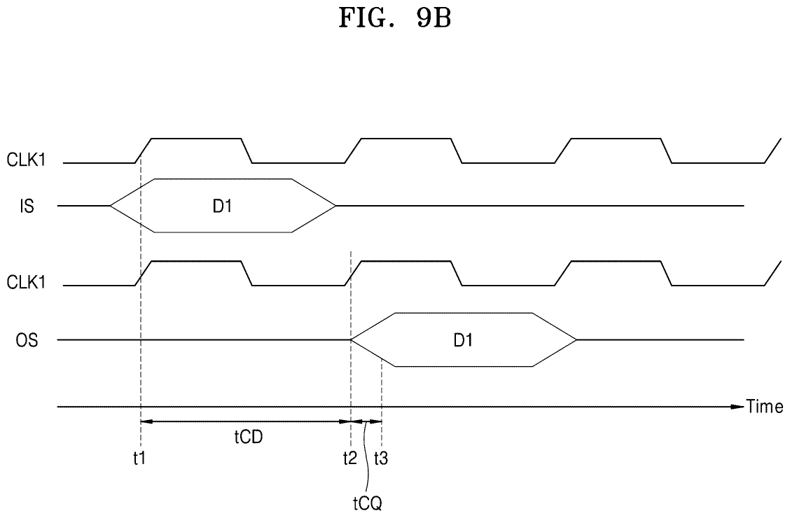

FIGS. 9A and 9B are timing diagrams for describing the operation of the RCD of FIG. 1 according to one or more embodiments.

Referring to FIGS. 2, 9A, and 9B, the source circuit 1311 may receive the first clock signal CLK1, and the sink circuit 1313 may receive the second clock signal CLK2 generated by delaying the first clock signal CLK1 by a clock delay. FIG. 9A shows a case where the operating circuit 1310 receives the first clock signal CLK1 of the first frequency feq1 (e.g., a high frequency) and the second clock signal CLK2 of the first frequency feq1, and FIG. 9B shows a case where the operating circuit 1310 receives the first clock signal CLK1 of the second frequency feq2 (e.g., a low frequency) and the second clock signal CLK2 of the second frequency feq2. The first frequency feq1 may refer to the maximum frequency required by the standard, and the second frequency feq2 may refer to the minimum frequency required by the standard. The logic propagation delay margin tPDM_LOGIC may be longer than the period of the first clock signal CLK1 of the first frequency feq1 and shorter than the period of the first clock signal CLK1 of the second frequency feq2.

Referring to FIG. 9A, at a first time point t1, the first clock signal CLK1 may rise from a logic low level to a logic high level. At the first time point t1, a source flip-flop SFF may sample first data D1 of the input signal IS in response to the rising edge of the first clock signal CLK1. Since the logic propagation delay margin tPDM_LOGIC is longer than the period of the first clock signal CLK1 of the first frequency feq1, the combination logic circuit 1312 may output first data D1 of the output combination signal oCS after a second time point t2.

The second clock signal CLK2 may be generated based on the first clock signal CLK1. The second clock signal CLK2 may be a clock signal delayed by a clock delay tCD from the first clock signal CLK1. The clock delay tCD may be determined based on the propagation delay margin tPDM or the logic propagation delay margin tPDM_LOGIC. The clock delay tCD may be computed based on the propagation delay margin tPDM or the logic propagation delay margin tPDM_LOGIC. The clock delay tCD may be identical or similar to the propagation delay margin tPDM or the logic propagation delay margin tPDM_LOGIC. The clock delay tCD may be a time reduced by the clock-output delay tCQ from the logic propagation delay margin tPDM_LOGIC. The clock delay tCD may be the time reduced by the clock-output delay tCQ from the propagation delay margin tPDM.

At the second time point t2, the second clock signal CLK2 may transition from a logic low level to a logic high level. At the second time point t2, the sink flip-flop FFS may sample the first data D1 of the output combination signal oCS in response to the rising edge of the second clock signal CLK2. The sink flip-flop FFS may output first data D1 of the output signal OS through the output terminal Q at a third time point t3 after the clock-output delay tCQ from the second time point t2. Therefore, the RCD 1300 may satisfy the propagation delay margin tPDM required by the standard.

Referring to FIG. 9B, at a first time point t1, the first clock signal CLK1 may rise from a logic low level to a logic high level. At the first time point t1, a source flip-flop SFF may sample first data D1 of the input signal IS in response to the rising edge of the first clock signal CLK1. The combination logic circuit 1312 may output first data D1 of the output combination signal oCS after a second time point t2.

At the second time point t2, the second clock signal CLK2 may transition from a logic low level to a logic high level. At the second time point t2, the sink flip-flop FFS may sample the first data D1 of the output combination signal oCS in response to the rising edge of the second clock signal CLK2. The sink flip-flop FFS may output first data D1 of the output signal OS through the output terminal Q at a third time point t3 after the clock-output delay tCQ from the second time point t2. Therefore, the RCD 1300 may satisfy the propagation delay margin tPDM required by the standard.

As described above, the source circuit 1311 may receive the first clock signal CLK1, and the sink circuit 1313 may receive the second clock signal CLK2. The second clock signal CLK2 may be a clock signal delayed by a clock delay (e.g., the logic propagation delay margin tPDM_LOGIC) from the first clock signal CLK1. Since the logic propagation delay margin tPDM_LOGIC is longer than the propagation delay margin tLOGIC of the combination logic circuit 1312, the sink circuit 1313 may stably sample the output combination signal oCS. Therefore, the sink circuit 1313 may always output the output signal OS after a certain amount of time (e.g., the logic propagation delay margin tPDM_LOGIC).

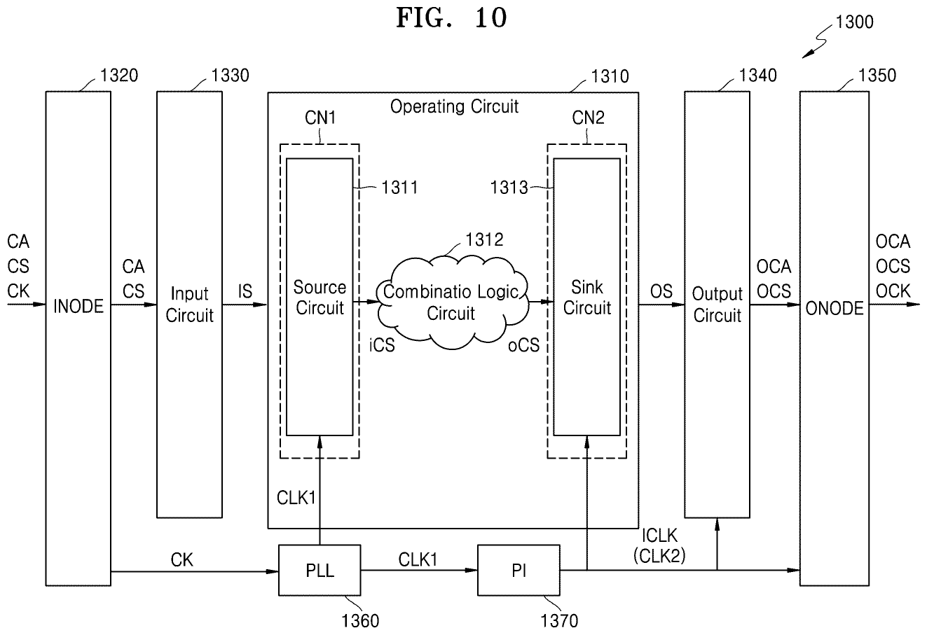

FIG. 10 is a block diagram showing the RCD of FIG. 1 according to one or more embodiments.

Referring to FIGS. 1, 2, and 10, the RCD 1300 may include the operating circuit 1310, the input node 1320, the input circuit 1330, the output circuit 1340, the output node 1350, the PLL 1360, and the phase interpolator 1370. For convenience of explanation, detailed descriptions of the components already given above are omitted.

The operating circuit 1310 may include the source circuit 1311, the combination logic circuit 1312, and the sink circuit 1313. The operating circuit 1310 may receive the input signal IS from the input circuit 1330. The operating circuit 1310 may receive the first clock signal CLK1 from the PLL 1360. The operating circuit 1310 may receive the second clock signal CLK2 from the phase interpolator 1370. The second clock signal CLK2 may be the interpolated clock signal ICLK. The operating circuit 1310 may output output signal OS to the output circuit 1340.

The PLL 1360 may generate the first clock signal CLK1. The PLL 1360 may provide the first clock signal CLK1 to the source circuit 1311. The PLL 1360 may provide the first clock signal CLK1 to the phase interpolator 1370.

The phase interpolator 1370 may receive the first clock signal CLK1. The phase interpolator 1370 may generate the second clock signal CLK2, which is the interpolated clock signal ICLK, based on the first clock signal CLK1. The phase interpolator 1370 may provide the second clock signal CLK2 to the sink circuit 1313. The phase interpolator 1370 may provide the second clock signal CLK2 to the output circuit 1340. The phase interpolator 1370 may output the second clock signal CLK2 as the output clock signal OCK through the output node 1350.

The source circuit 1311 configured to receive the first clock signal CLK1 may be included in the first clock network CN1. The sink circuit 1313 configured to receive the second clock signal CLK2 may be included in the second clock network CN2.

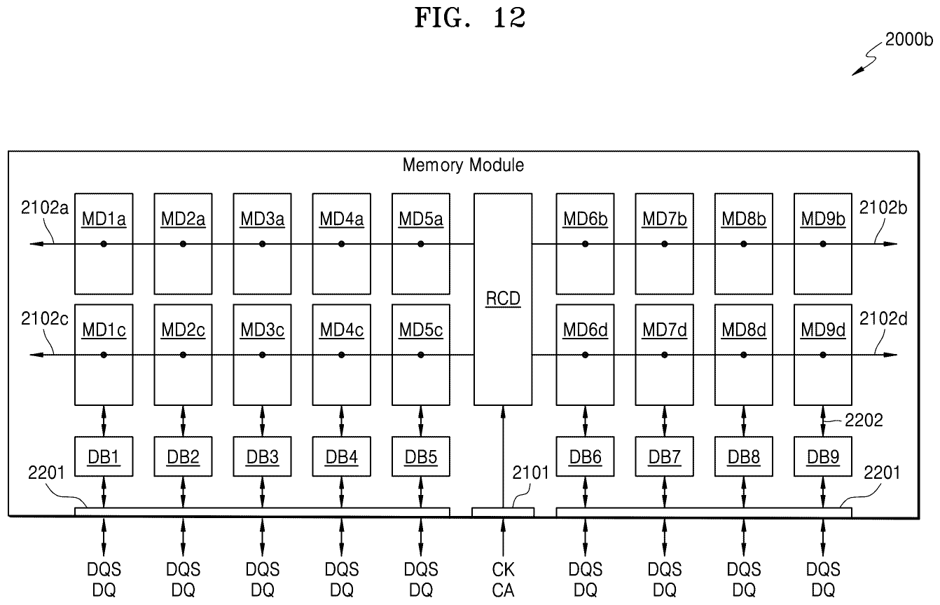

FIGS. 11 and 12 are block diagrams showing memory modules according to one or more embodiments, respectively.

Memory modules 2000a and 2000b may each be a dual in-line memory module (DIMM) that complies with the Joint Electron Device Engineering Council (JEDEC) standard. For example, the memory module 2000a may be a registered DIMM (RDIMM), and the memory module 2000b may be a load reduced DIMM (LRDIMM). A memory module according to one or more embodiments may include, in addition to the above-stated examples, a fully buffered DIMM (FB-DIMM), a small outline DIMM (SO-DIMM), and/or another memory module (e.g., a single in-line memory module (SIMM)).

The memory module 2000a may include pins 2101 and 2201, a CA bus 2102a, 2102b, DQ buses 2202, memory devices MD1 to MD9, and an RCD. The memory devices MD1 to MD9 may be substantially identical or similar to the memory devices 1400 of FIG. 1, and the RCD may be substantially identical or similar to the RCD 1300 of FIG. 1. An operating circuit of the RCD may include a plurality of clock networks. A source circuit of the operating circuit may be included in a first clock network, and a sink circuit of the operating circuit may be included in a second clock network. Therefore, a constant propagation delay margin may be achieved regardless of frequency changes.

The pins 2101 may include clock pins and CA pins that respectively receive the clock signal CK and the CA signals CA from the memory controller 1100. The pins 2201 may include DQ pins and DQS pins that respectively receive write) DQ signals DQ and (write) DQS signals DQS from the memory controller 1100 or respectively receive (read) DQ signals DQ and (read) DQS signals DQS from the memory devices MD1 to MD9. The DQ buses 2202 may include transmission paths that physically and electrically connect the pins 2201 of the memory module 2000a to pins of the memory devices MD1 to MD9. The RCD may receive the clock signal CK and the CA signals CA through the pins 2101. The RCD may transmit the clock signal CK and the CA signals CA to memory devices MD1 to MD5 through the CA bus 2102a and to memory devices MD6 to MD9 through the CA bus 2102b. The RCD may buffer the clock signal CK and the CA signals CA. Although the CA bus 2102 is shown as being shared by the memory devices MD1 to MD9, the DQ buses 2202 may be respectively provided for the memory devices MD1 to MD9 and may not be shared by the memory devices MD1 to MD9.

The memory module 2000b may further include memory devices MD1a to MD5a, MD1c to MD5c, MD6b to MD9b, and MD6d to MD9d and data buffers DB1 to DB9, a CA bus 2102c, and a CA bus 2102d, as compared to the memory module 2000a. The CA bus 2102a may include transmission paths that physically and electrically connect the RCD to pins of each of memory devices MD1a to MD5a. The CA bus 2102b may include transmission paths that physically and electrically connect the RCD to pins of each of memory devices MD6b to MD9b. The CA bus 2102c may include transmission paths that physically and electrically connect the RCD to pins of each of memory devices MD1c to MD5c. The CA bus 2102d may include transmission paths that physically and electrically connect the RCD to pins of each of memory devices MD6d to MD9d. The RCD may receive the clock signal CK and the CA signals CA through the pins 2101. The RCD may transmit the clock signal CK and the CA signals CA to the memory devices MD1a to MD5a through the CA bus 2102a, to the memory devices MD6b to MD9b through the CA bus 2102b, to the memory devices MD1c to MD5c through the CA bus 2102c, and to the memory devices MD6d to MD9d through the CA bus 2102d.

A data buffer DB1 may be placed on the DQ buses 2202 between memory devices MD1a and MD1c and the memory controller 1100. The data buffer DB1 may be physically and electrically connected to pins of each of the memory devices MD1a and MD1c and may be physically and electrically connected to the pins 2201. The data buffer DB1 may buffer the DQ signals DQ and the DQS signals DQS for the memory devices MD1a and MD1c. The data buffer DB1 may transmit buffered DQ signals DQ and buffered DQS signals DQS to the memory devices MD1a and MD1c or the memory controller 1100. Other data buffers DB2 to DB9 may also be implemented similarly as the data buffer DB1. In the embodiment, one sides of the memory modules 2000a and 2000b are illustrated in FIGS. 11 and 12, but memory devices, data buffers, etc. may also be attached to the other sides of the memory modules 2000a and 2000b. For example, memory devices attached to one side of each of the memory modules 2000a and 2000b may form ranks. Also, a number of memory devices included in the memory modules 2000a and 2000b is not limited to those shown in FIGS. 11 and 12.

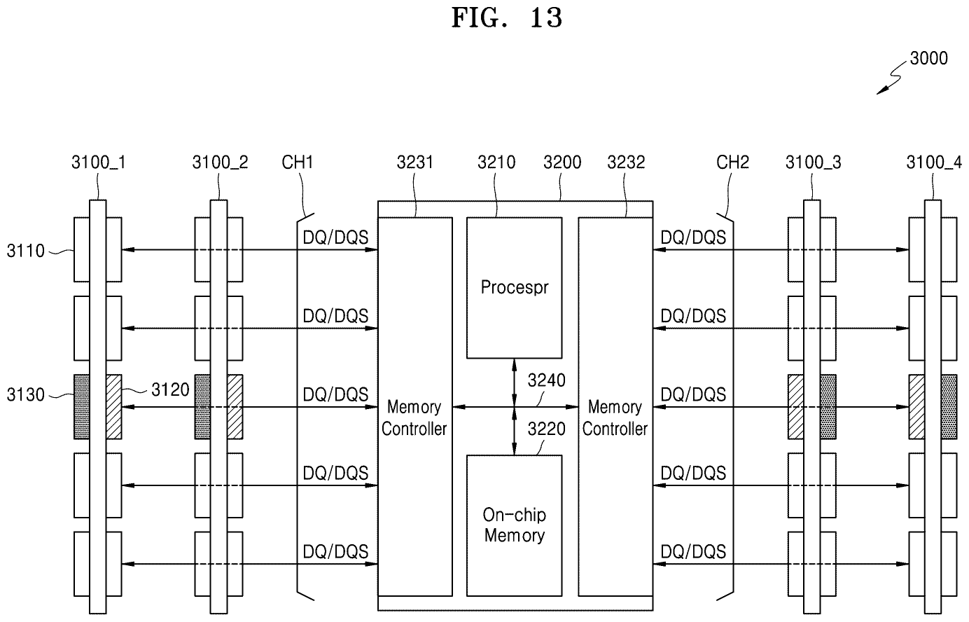

FIG. 13 is a block diagram illustrating a computing system according to one or more embodiments.

A computing system 3000 may correspond to the electronic device 1000 described above and may include memory modules 3100_1 to 3100_4 and a host 3200. The memory modules 3100_1 to 3100_4 may correspond to memory modules 1200, 2000a, and/or 2000b describe above. A memory module 3100_1 may include a plurality of memory devices 3110, an RCD 3120, and a power management integrated circuit (PMIC) 3130. The plurality of memory devices 3110 may each be implemented substantially identical or similar to the memory devices 1400 of FIG. 1. The RCD 3120 may be substantially identical or similar to the RCD 1300 of FIG. 1, receive a CK signal and a CA signal transmitted from the host 3200, and transmit the received CK signal and the received CA signal to the plurality of memory devices 3110.

An operating circuit of the RCD 3120 may include a plurality of clock networks. A source circuit of an operating circuit may be included in a first clock network, and a sink circuit of the operating circuit may be included in a second clock network. Therefore, a constant propagation delay margin may be achieved regardless of frequency changes.

The PMIC 3130 may supply power voltages to components 3110 and 3120 within the memory module 3100_1. Memory modules 3100_2 to 3100_4 may be implemented substantially identical or similar to the memory module 3100_1. Memory modules 3100_1 and 3100_2 may be assigned to a channel CH1. Memory modules 3100_3 and 3100_4 may be assigned to a channel CH2. The channel CH1 may include input/output paths for the memory modules 3100_1 and 3100_2 and the channel CH2 may include input/output paths for the memory modules 3100_3 and 3100_4. A number of channels, a number of memory devices, a number of memory modules, and a number of memory modules per channel illustrated herein are only examples. The host 3200 may be an application processor (AP), a system-on-chip (SoC), etc. The host 3200 may include a processor 3210, an on-chip memory 3220, memory controllers 3231 and 3232, and a system bus 3240 interconnecting the above-stated components. The processor 3210 may execute various software (e.g., application programs, operating systems, file systems, device drivers, etc.) loaded into the on-chip memory 3220. The processor 3210 may include a homogeneous multi-core or a heterogeneous multi-core. For example, the processor 3210 may be any one of a central processing unit (CPU), an image signal processing unit (ISP), a digital signal processing unit (DSP), a graphics processing unit (GPU), a vision processing unit (VPU), and a neural processing unit (NPU). Application programs, operating systems, file systems, device drivers, etc. for driving the computing system 3000 may be loaded into the on-chip memory 3220. The on-chip memory 3220 may be implemented inside the host 3200 and may include an SRAM, a register, etc. having a faster data input/output speed than the memory modules 3100_1 to 3100_4. The on-chip memory 3220 may also be referred to as a buffer memory. The memory controllers 3231 and 3232 may correspond to the above-described memory controller 1100. The memory controller 3231 may access the memory modules 3100_1 and 3100_2 through the channel CH1 based on the control of the processor 3210. The memory controller 3232 may access the memory modules 3100_3 and 3100_4 through the channel CH2 based on the control of the processor 3210.

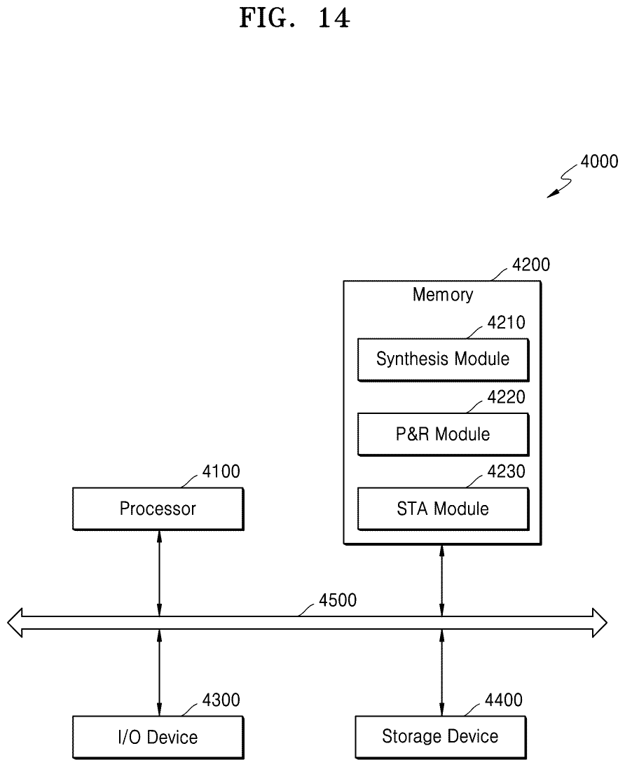

FIG. 14 is a block diagram showing a computing system for designing an integrated circuit, according to one or more embodiments.

Referring to FIG. 14, a computing system 4000 for designing an integrated circuit (hereinafter referred to as an ‘integrated circuit design system’) may include a processor 4100, a memory 4200, an input/output device 4300, a storage device 4400, and a bus 4500. According to one or more embodiments, the integrated circuit design system 4000 may be implemented as an integrated device, and thus may be referred to as an integrated circuit design device. The integrated circuit design system 4000 may be provided as a dedicated device for designing an integrated circuit of a semiconductor device, but may also be a computer for operating various simulation tools and/or design tools.

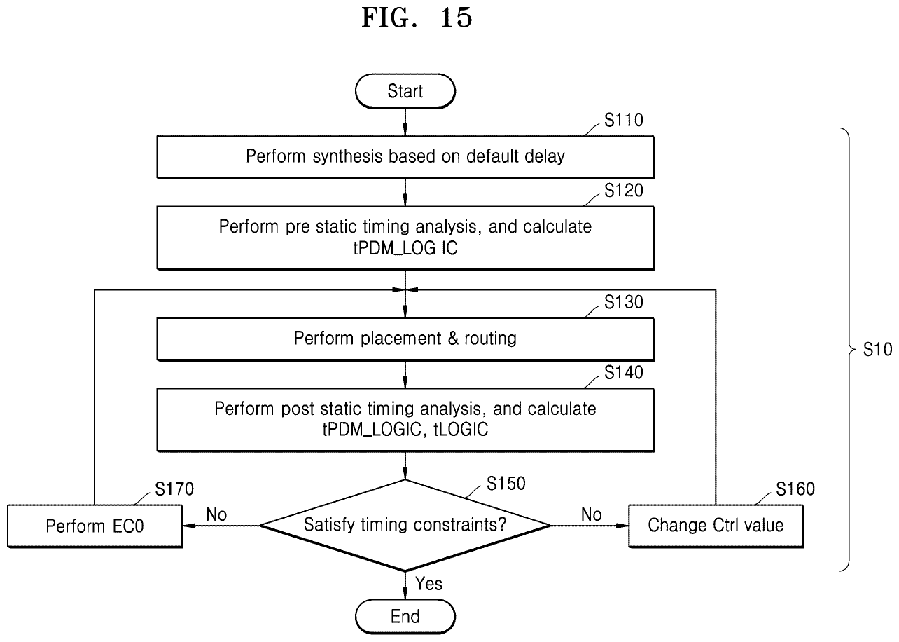

An integrated circuit designed by the computing system 4000 may be the RCD 1300 of FIG. 1. The processor 4100 may be configured to execute instructions that perform at least one of various operations for designing an integrated circuit. The processor 4100 may communicate with the memory 4200, the input/output device 4300, and the storage device 4400 via the bus 4500. The processor 4100 may execute design operations of an integrated circuit by driving a synthesis module 4210, a placement and routing (P&R) module 1220, and a static timing analysis (STA) module 1230 loaded into the memory 4200. An operation of each module will be described later with reference to FIG. 15.

The memory 4200 may store the synthesis module 4210, the P&R module 4220, and the STA module 4230. The synthesis module 4210, the P&R module 4220, and the STA module 4230 may be loaded from the storage device 4400 into the memory 4200.

The synthesis module 4210 may be a program including a plurality of instructions for performing logic synthesis operations and design for testability (DFT) logic insertion. The P&R module 4220 may be a program including a plurality of instructions for performing a P&R operation. The STA module 4230 may be a program including a plurality of instructions for performing an STA operation. The memory 4200 may be a volatile memory, such as an SRAM or a DRAM, or a non-volatile memory, such as a PRAM, an MRAM, an ReRAM, an FRAM, or a NOR flash memory.

The input/output device 4300 may control a user input and a user output from a user interface device. For example, the input/output device 4300 may include an input device such as a keyboard, a mouse, a touchpad, etc., and may receive input data defining an integrated circuit. For example, the input/output device 4300 may include an output device such as a display, a speaker, etc., to display placement results, routing results, STA results, etc. The storage device 4400 may store various data related to the synthesis module 4210, the P&R module 4220, and the STA module 4230. The storage device 4400 may include a memory card (multi-media card (MMC), an embedded MMC (eMMC), secure digital (SD), MicroSD, etc.), a solid state drive (SSD), a hard disk drive (HDD), etc.

FIG. 15 is a flowchart of a method of designing an integrated circuit, according to one or more embodiments.

Referring to FIGS. 14 and 15, a method of designing an integrated circuit includes operations of designing a layout for an integrated circuit, which may be performed by using a tool for designing an integrated circuit. Here, the tool for designing an integrated circuit may include a program and/or software module including a plurality of instructions executed by at least one processor and may be stored in a computer-readable storage medium. Therefore, the method of designing an integrated circuit may be referred to as a computer-implemented method of designing an integrated circuit. The method of designing an integrated circuit of FIG. 15 may be performed by the computing system 4000 of FIG. 14. An integrated circuit designed according to the method according to one or more embodiments may include the RCD 1300 of FIG. 1.

Referring to FIGS. 14 and 15, in operation S110, the processor 4100 may perform a synthesis operation by using the synthesis module 4210. “Synthesis” may be an operation of generating a netlist by converting input data for an integrated circuit into a hardware form consisting of logic gates and may be referred to as “logic synthesis”. The input data may be data defined in an abstract form, e.g., at a register transfer level (RTL), regarding a behavior of an integrated circuit. The netlist may be generated from RTL codes by using a standard cell library and may be a gate-level netlist. According to one or more embodiments, an RTL code may be provided as an input file to a synthesis tool, and a netlist may be output as an output file from the synthesis tool. The netlist may include information regarding a plurality of standard cells and interconnections between the plurality of standard cells.

The processor 4100 may select a plurality of standard cells by performing (or operating) the synthesis module 4210. The processor 4100 may perform synthesis based on a default delay. The processor 4100 may set the control signal Ctrl to a pre-set default value and perform synthesis.

In operation S120, the processor 4100 may perform a pre-static timing analysis (pre-STA) operation by using the STA module 4230. For example, the processor 4100 may perform a pre-STA operation based on the netlist. The processor 4100 may perform a pre-STA operation and compute the logic propagation delay margin tPDM_LOGIC.

At operation S130, the processor 4100 may use the P&R module 4220 to place-and-route standard cells defining an integrated circuit and generate layout data for the integrated circuit. For example, the layout data may be data in a graphic design system (GDS)-II format. According to one or more embodiments, the netlist may be provided as an input file to the P&R module 4220, and the layout data may be output as an output file from the P&R module 4220. The P&R module 4220 may place standard cells and route nets included in placed standard cells. The P&R module 4220 may generate layout data for the integrated circuit when routing is completed.

In operation S140, the processor 4100 may perform a post-static timing analysis (post-STA) operation on the layout data by using the STA module 4230. The processor 4100 may perform a post-STA on the layout data and compute the logic propagation delay margin tPDM_LOGIC and the propagation delay margin tLOGIC of the combination logic circuit 1312.

In operation S150, the STA module 4230 may determine whether a timing constraint is satisfied. The STA module 4230 may determine whether a timing violation has occurred. “Timing analysis” refers to an operation of determining whether a timing path included in an integrated circuit satisfy a timing constraint, and, based on a result of the determination, selecting a timing path or a timing critical path of the integrated circuit whose total timing delay from an input (e.g., a start point) to an output (e.g., an end point) exceeds a timing requirement from among timing paths. The timing constraint may include a setup timing constraint and a hold timing constraint. The STA module 4230 may perform a timing analysis and generate a timing report or timing analysis result information.

For example, the STA module 4230 may determine whether the propagation delay margin tPDM required by the standard is satisfied based on the logic propagation delay margin tPDM_LOGIC and the propagation delay margin tLOGIC of the combination logic circuit 1312.

When it is determined that no timing violation has occurred, operations of the method may be terminated. On the other hand, when a timing violation has occurred, operation S160 or operation S170 may be performed. According to one or more embodiments, the processor 4100 may proceed to either operation S160 or operation S170.

In operation S160, the value of the control signal Ctrl may be changed. To satisfy the propagation delay margin tPDM required by the standard, the control signal Ctrl having a changed value may be input as input data through the input/output device 4300. As the control signal Ctrl is changed, the clock delay tCD may be adjusted. Afterwards, the processor 4100 may perform operation S130 again.

At operation S170, an engineering change orders (ECO) operation may be performed. The engineering change orders (ECO) operation may be performed based on a timing report or timing analysis results information. For example, a buffer or a delay circuit may be added or removed to or from the path of the second clock signal CLK2. Afterwards, the processor 4100 may perform operation S130 again. While FIG. 15 illustrates that either operation S160 or operation S170 may be performed, the processor 43100 may perform both operations S160 and S170 in one or more embodiments.

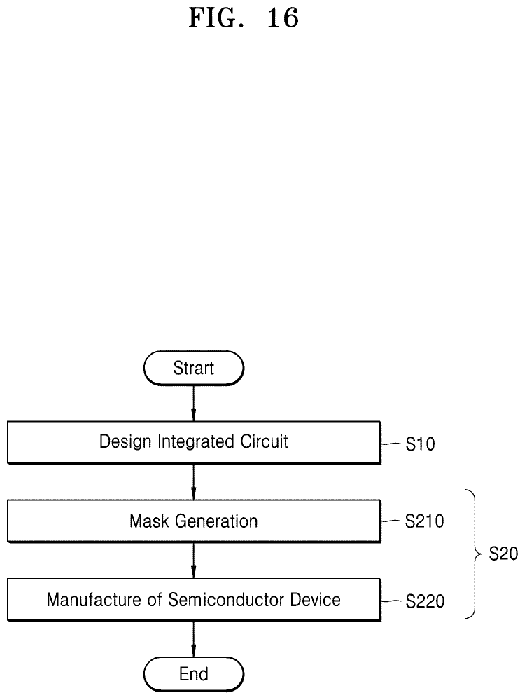

FIG. 16 is a flowchart of a method of manufacturing an integrated circuit, according to one or more embodiments.

Referring to FIGS. 15 and 16, the method for manufacturing an integrated circuit may be divided into an integrated circuit design process S10 (as illustrated in FIG. 15) and an integrated circuit manufacturing process S20. The integrated circuit manufacturing process S20 may be a process of manufacturing a semiconductor device according to an integrated circuit based on layout data generated in the integrated circuit design process S10 and may be performed in a semiconductor process module. An integrated circuit manufactured according to the method in one or more embodiments may include the RCD 1300 of FIG. 1.

In operation S210, a mask may be fabricated based on layout data. First, optical proximity correction (OPC) may be performed based on the layout data. Here, the OPC refers to a process of changing a layout by reflecting an error due to an optical proximity effect. Subsequently, a mask may be fabricated according to a layout changed according to a result of performing the OPC. At this time, the mask may be fabricated by using a layout reflecting the OPC, e.g., GDS-II reflecting the OPC.

In operation S220, a semiconductor device having an integrated circuit implemented by using a mask may be manufactured. A semiconductor device having implemented thereon an integrated circuit may be formed by performing various semiconductor processes on a semiconductor substrate such as a wafer using a plurality of masks. For example, a process using the mask may refer to a patterning process through lithography. A desired pattern may be formed on a semiconductor substrate or a material layer through such a patterning process. Here, the semiconductor processes may include a deposition process, an etching process, an ion process, a cleaning process, etc. Also, the semiconductor process may include a packaging process for mounting a semiconductor device on a printed circuit board (PCB) and sealing the semiconductor device with a sealing material or may include a test process for testing a semiconductor device or a package.

While the disclosure has been particularly shown and described with reference to example embodiments thereof, it will be understood that various changes in form and details may be made therein without departing from the spirit and scope of the following claims and their equivalents.

What is claimed is:

1. A register clock driver comprising:
an input node configured to receive an input signal from a memory controller;
an operating circuit configured to buffer the input signal and comprising a source circuit, a combination logic circuit, and a sink circuit, the source circuit including source flip-flops, and the sink circuit including sink flip-flops; and
an output node configured to output an output signal to a memory device,
wherein the source circuit is configured to receive a first clock signal, and the sink circuit is configured to receive a second clock signal different from the first clock signal, and
wherein the second clock signal is a clock signal delayed by a clock delay from the first clock signal, and the clock delay is determined based on a propagation delay margin.

2. The register clock driver of claim 1, wherein the source circuit is included in a first clock network, and
wherein the sink circuit is included in a second clock network.

3. The register clock driver of claim 1, further comprising a phased locked loop configured to receive a clock signal from the input node and generate the first clock signal based on the clock signal, and
wherein the first clock signal is transmitted to the source circuit through a buffer.

4. The register clock driver of claim 1, wherein the operating circuit further comprises a clock delay circuit configured to receive the first clock signal through a buffer and generate the second clock signal by delaying the first clock signal by the clock delay.

5. The register clock driver of claim 4, wherein the clock delay circuit comprises:
a first sub-delay circuit, a second sub-delay circuit, and a third sub-delay circuit; and
a multiplexer, and
wherein the multiplexer is configured to receive a first intermediate clock signal output from the first sub-delay circuit, a second intermediate clock signal output from the second sub-delay circuit, and a third intermediate clock signal output from the third sub-delay circuit, and select one of the first to third intermediate clock signals and output a selected intermediate clock signal as the second clock signal, in response to a control signal.

6. The register clock driver of claim 1, wherein each of the source flip-flops is configured to sample the received input signal in response to the first clock signal and output the sampled signal as an input combination signal to the combination logic circuit.

7. The register clock driver of claim 1, wherein each of the sink flip-flops is configured to sample the received output combination signal in response to the second clock signal and output the sampled signal as the output signal.

8. The register clock driver of claim 1, further comprising a phase interpolator configured to generate an interpolated clock signal by controlling a phase of the first clock signal,
wherein the second clock signal is the interpolated clock signal.

9. The register clock driver of claim 1, wherein the clock delay is a time reduced by a clock-output delay from the propagation delay margin.

10. A memory module comprising:
a plurality of memory devices, each memory device of the plurality of memory devices comprising a memory cell array; and
a register clock driver connected to the plurality of memory devices,
wherein the register clock driver comprises:
an input node configured to receive a command/address signal from a memory controller;
an output node configured to output an output command/address signal to the plurality of memory devices; and
an operating circuit configured to buffer the command/address signal and comprising a source circuit, a combination logic circuit, and a sink circuit, the source circuit including source flip-flops, and the sink circuit including sink flip-flops,
wherein each of the source flip-flops is configured to sample the command/address signal in response to a first clock signal of a first clock network, and each of the sink flip-flops is configured to sample a signal output from the combination logic circuit in response to a second clock signal of a second clock network, and
wherein the second clock signal is a clock signal delayed by a clock delay from the first clock signal, and the clock delay is determined based on a propagation delay margin.

11. The memory module of claim 10, further comprising:
a clock input node configured to receive a clock signal from the memory controller; and
a phased locked loop configured to receive the clock signal through the clock input node and generate the first clock signal based on the clock signal.

12. The memory module of claim 10, wherein the operating circuit further comprises a clock delay circuit configured to receive the first clock signal through a buffer and generate the second clock signal by delaying the first clock signal by the clock delay.

13. The memory module of claim 12, wherein the clock delay circuit comprises:
a first sub-delay circuit, a second sub-delay circuit, and a third sub-delay circuit; and
a multiplexer, and
wherein the multiplexer is configured to receive a first intermediate clock signal output from the first sub-delay circuit, a second intermediate clock signal output from the second sub-delay circuit, and a third intermediate clock signal output from the third sub-delay circuit, and select one of the first to third intermediate clock signals and output a selected intermediate clock signal as the second clock signal, in response to a control signal.

14. The memory module of claim 10, further comprising a phase interpolator configured to generate an interpolated clock signal by controlling a phase of the first clock signal,
wherein the second clock signal is the interpolated clock signal.

15. A register clock driver comprising:
an operating circuit configured to buffer a command/address signal and comprising a source circuit, a combination logic circuit, a sink circuit, and a clock delay circuit, the source circuit including source flip-flops, and the sink circuit including sink flip-flops; and
a phased locked loop configured to receive a clock signal and generate a first clock signal based on the clock signal,
wherein the clock delay circuit is configured to receive the first clock signal and generates a second clock signal by delaying the first clock signal by a clock delay,
wherein each of the source flip-flops is configured to sample the command/address signal in response to the first clock signal of a first clock network and output the sampled command/address signal to the combination logic circuit, and
wherein each of the sink flip-flops is configured to sample a signal output from the combination logic circuit and output the sampled signal in response to the second clock signal of a second clock network.

16. The register clock driver of claim 15, wherein the clock delay is determined based on a propagation delay margin.

17. The register clock driver of claim 15, wherein the clock delay circuit comprises:
a first sub-delay circuit, a second sub-delay circuit, and a third sub-delay circuit; and
a multiplexer, and
wherein the multiplexer is configured to receive a first intermediate clock signal output from the first sub-delay circuit, a second intermediate clock signal output from the second sub-delay circuit, and a third intermediate clock signal output from the third sub-delay circuit, and select one of the first to third intermediate clock signals and output a selected intermediate clock signal as the second clock signal, in response to a control signal.

18. The register clock driver of claim 15, further comprising a phase interpolator configured to generate an interpolated clock signal by controlling a phase of the first clock signal,
wherein the second clock signal is the interpolated clock signal.

19. The register clock driver of claim 18, further comprising an output circuit configured to receive an output signal, which is output from the sink circuit, and output an output command/address signal through an output node,
wherein the output circuit comprises a flip-flop configured to sample a signal output from the sink circuit in response to the interpolated clock signal; and a buffer configured to buffer the sampled signal of the flip-flop and output the buffered signal as the output command/address signal.

20. The register clock driver of claim 15, further comprising an input circuit configured to receive the command/address signal through an input node,
wherein the input circuit comprises a buffer configured to buffer the command/address signal received through the input node; and a flip-flop configured to sample a signal received from the buffer in response to a clock signal and output the sampled signal of the flip-flop to the operating circuit.
